(19) United States
(12) Patent Application Publication
(10) Pub. No.: US 2025/0336772 A1
(43) Pub. Date: Oct. 30, 2025

(54) SEMICONDUCTOR DEVICES WITH NANO-VIAS, SUCH AS NANO-THROUGH-SILICON VIAS LANDING ON MIDDLE-OF-LINE OR BACK-END-OF-LINE LAYERS

(71) Applicant: Micron Technology, Inc., Boise, ID (US)

(72) Inventors: Bharat Bhushan, Taichung (TW); Terrence B. McDaniel, Boise, ID (US); Wei Zhou, Boise, ID (US); Akshay N. Singh, Boise, ID (US); Kunal R. Parekh, Boise, ID (US)

(21) Appl. No.: 19/182,605

(22) Filed: Apr. 18, 2025

Related U.S. Application Data
(60) Provisional application No. 63/640,795, filed on Apr. 30, 2024.

(51) Int. Cl. H01L 23/48; H01L 23/00; H01L 25/07; H10B 80/00

(52) U.S. Cl. CPC H01L 23/481; H01L 24/05; H01L 24/08; H01L 25/074; H01L 2224/05009; H01L 2224/08145; H01L 2225/06544; H01L 2225/06565; H10B 80/00

(57) ABSTRACT

Semiconductor devices with nano-vias, such as nano-through-silicon vias landing on middle-of-line (MOL) or back-end-of-line (BEOL) layers, are disclosed herein. In one embodiment, a semiconductor die includes a first side, a bond pad at the first side, a landing pad within an intermediate layer of the semiconductor die, and a via extending from the bond pad to the landing pad. The via can have an aspect ratio of height to width of 6:1 or less. The intermediate layer can be positioned between the first side and a second side of the semiconductor die opposite the first side. In some embodiments, the intermediate layer is a MOL layer. In other embodiments, the intermediate layer is a BEOL layer. The semiconductor die can be a memory die, a logic die, a central processing unit (CPU) die, a graphics processing unit (GPU) die, a tensor processing unit (TPU) die, or another type of die.

### CROSS-REFERENCE TO RELATED APPLICATION(S)

The present application claims priority to U.S. Provisional Patent Application No. 63/640,795, filed Apr. 30, 2024, the disclosure of which is incorporated herein by reference in its entirety.

### TECHNICAL FIELD

The present disclosure relates generally to semiconductor devices. For example, several embodiments of the present disclosure relate to semiconductor dies (e.g., memory dies) having via structures, such as nano-through-silicon vias (nano-TSVs or nTSVs), that land on respective landing pad structures formed in one or more intermediate layers (e.g., one or more middle-of-line (MOL) layers and/or one or more back-end-of-line (BEOL) layers) of the semiconductor dies.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which supply voltages, signals, etc. are transmitted to and from the integrated circuitry. After dies are formed, they are “packaged” to couple the bond pads to a larger array of electrical terminals that can be more easily coupled to various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a partially schematic, cross-sectional side view of a semiconductor device configured in accordance with various embodiments of the present technology.

FIG. 1B is an enlarged, detail view of a semiconductor die of FIG. 1A corresponding to an area of detail shown in FIG. 1A.

FIG. 2A is a partially schematic, cross-sectional side view of another semiconductor device configured in accordance with various embodiments of the present technology.

FIG. 2B is an enlarged, detail view of the semiconductor device of FIG. 2A corresponding to an area of detail shown in FIG. 2A.

FIG. 2C is a partially schematic view of the semiconductor device 250 of FIGS. 2A and 2B incorporated into a larger system in accordance with various embodiments of the present technology.

FIG. 3 is a flow diagram illustrating a method of manufacturing a semiconductor device in accordance with various embodiments of the present technology.

FIGS. 4A-4F are partially schematic, cross-sectional side views of a semiconductor device illustrating a series of steps for fabricating a semiconductor device in accordance with various embodiments of the present technology.

FIG. 5 is a partially schematic view of a system that includes a semiconductor device assembly configured in accordance with various embodiments of the present technology.

### DETAILED DESCRIPTION

Specific details of several embodiments of semiconductor devices with via structures, such as nano-TSVs, that land on respective landing pad structures formed in one or more intermediate layers (e.g., one or more MOL layers and/or one or more BEOL layers) of the semiconductor devices are described below. As used herein, the term nano-TSV (abbreviated nTSV) refers to a TSV having an aspect ratio of height to width of less than or equal to 7:1, such as less than or equal to 6:1, less than or equal to 5:1, less than or equal to 4:1, or smaller. For the sake of clarity and example, the present technology is primarily described below in the context of memory devices, such as dynamic random-access memory (DRAM) devices. Additionally, or alternatively, several embodiments of the present technology are described below in the context of one or more stacks of semiconductor dies (e.g., stacks of DRAM dies). In some embodiments of the present technology, the stack(s) of semiconductor dies can be incorporated into larger systems. For example, a single stack of semiconductor dies of the present technology can be incorporated into a high-bandwidth memory (HBM) device. As another example, a wafer can be diced to produce one or more semiconductor devices with multiple stacks of semiconductor dies of the present technology coupled therewith at multiple lateral locations. As a specific implementation of this example, a semiconductor device with multiple stacks of semiconductor dies coupled therewith at multiple lateral locations can include (i) a logic die, a central processing unit (CPU), or a graphics processing unit (GPU) and (ii) a plurality of memory die stacks coupled therewith. Specifically, a three-dimensional integration of semiconductor devices can include stacked DRAM die of the present technology and workstation GPUs in a same package. It is appreciated that the present technology may also be employed in other types of semiconductor devices. For example, TSVs (e.g., nTSVs) and other via structures (e.g., via structures that may or may not extend through silicon, in particular) of the present technology can be employed or implemented in logic devices, three-dimensional (3D) NAND devices, chiplets, other types of memory devices, other types of memory systems, and/or other semiconductor devices. Such other implementations are within the scope of the present technology.

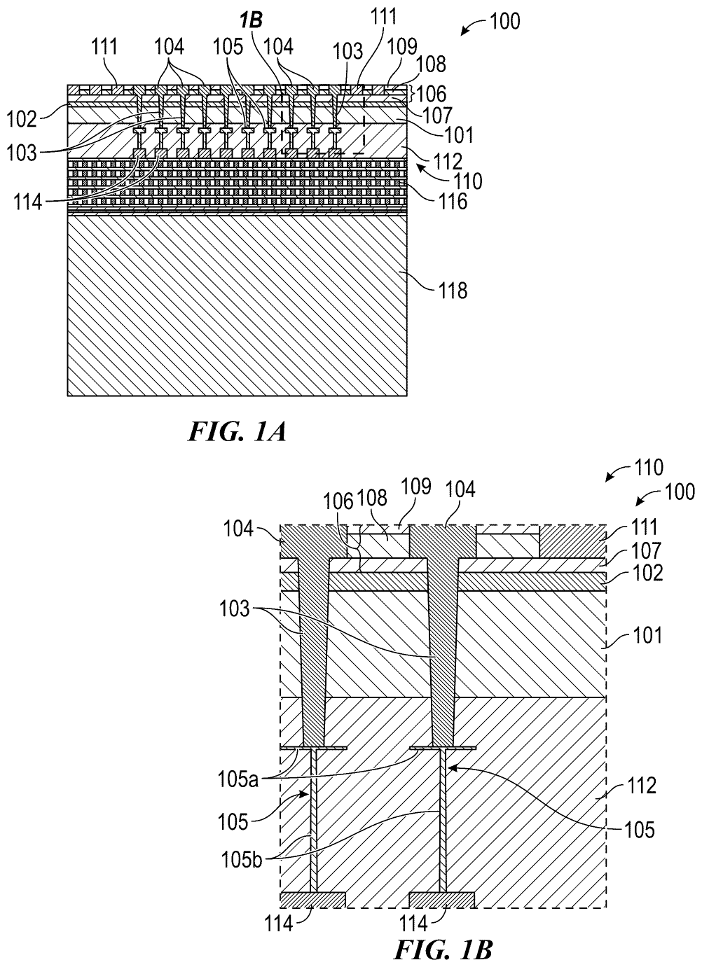

Specific details of several embodiments of the present technology are described herein with reference to FIGS. 1A-5. Although many of the embodiments are described herein with respect to semiconductor devices incorporating DRAM dies having TSVs (e.g., dual damascene, nano, and/or via last (VL) TSVs) that terminate at a landing pad structure in or at an intermediate layer, other applications and other embodiments in addition to those described herein are within the scope of the present technology. For example, the present technology can be directed to semiconductor devices incorporating other types of semiconductor die, such as other types of memory die. Further, a person of ordinary skill in the art will understand that embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in the semiconductor devices in view of the orientation shown in the drawings. For example, “bottom” can refer to a feature positioned closer to the bottom of a page than another feature. These terms, however, should be construed broadly to include semiconductor devices having other orientations, such as inverted or inclined orientations where top/bottom, over/under, above/below, up/down and left/right can be interchanged depending on the orientation.

Semiconductor devices generally have a die (e.g., a chip) that includes integrated circuitry with a high density of very small components. Typically, dies include an array of bond pads electrically coupled to the integrated circuitry. The bond pads are external electrical contacts through which supply voltages, signals, etc. are transmitted to and from the integrated circuitry through various layers of the dies using interconnect structures (e.g., TSVs) coupled to the bond pads. The bond pads of a semiconductor die are commonly arranged (e.g., spaced apart) at a given pitch. When the pitch is large, it is relatively easy to form TSVs and other interconnect structures using copper or another suitable material.

As industry continues to strive for smaller overall footprints of semiconductor devices, however, the pitch of bond pads on semiconductor dies is expected to decrease (e.g., by a factor of ten or more). As the pitch of bonds pads decreases, the aspect ratios of the heights of corresponding interconnect structures (e.g., vias, TSVs) to the widths of those interconnect structures increase. As the aspect ratios of these interconnect structures increase while their physical dimensions decrease, it becomes increasingly difficult to adequately form the interconnect structures without an unacceptably high risk of reliability issues, non-uniformity issues, and/or other types of issues.

As a specific example of the above problem, the inventors of the present technology expect that bond pads on future semiconductor dies will be arranged at less than or equal to approximately a 1.8 μm pitch, less than or equal to approximately a 1.6 μm pitch, or less than or equal to approximately a 1.4 μm pitch. At this pitch, the inventors expect that bond pads will be approximately 0.5 μm to 0.8 μm in width, meaning that TSVs and other interconnect structures coupled to the bond pads will likely be less than 0.8 μm in width, such as approximately 0.4 μm in width. Thus, for an interconnect structure that extends from a bond pad of a semiconductor die to a metal layer of back end of line (BEOL) layers of the semiconductor die, the aspect ratio of the height of the interconnect structure to its width is expected to reach approximately 10:1. At this physical scale, it can be extremely difficult to form interconnect structures with certain materials (e.g., copper) and achieve a 10:1 aspect ratio without frequently encountering reliability issues, non-uniformity issues, and other types of issues. One possible solution at this physical scale is to form such interconnect structures using different materials (e.g., using tungsten instead of copper). Use and deposition of these different materials (especially tungsten), however, can be costly, and formation of certain arrangements or structures (e.g., dual damascene) using these different materials may not be possible.

To address these concerns, several embodiments of the present technology are directed to semiconductor dies (and related apparatuses and systems) that include landing pad structures formed in one or more intermediate layers (e.g., one or more MOL layers and/or one or more BEOL layers) of the semiconductor dies, such as one or more intermediate layers positioned between a bond pad at a backside of a semiconductor die and a metal layer in BEOL layers of the semiconductor die. For example, each landing pad structure of a semiconductor die (i) can extend from an intermediate layer of the semiconductor die toward a metal layer in BEOL layers of the semiconductor die, and (ii) can provide a location in the intermediate layer at which a corresponding TSV can land or terminate. Thus, rather than extending an entire distance from a bond pad (e.g., at a backside of a semiconductor die) to the metal layer in the BEOL layers of the semiconductor die, a TSV of the present technology can extend from the bond pad to a corresponding landing pad structure in the intermediate layer of the semiconductor die. In turn, the corresponding landing pad structure can span all or a subset of the remaining distance between (i) the location at which the TSV terminates in the intermediate layer of the semiconductor die and (ii) the metal layer in the BEOL layers of the semiconductor die.

In other words, several embodiments of the present technology utilize landing pad structures formed in one or more intermediate layers of a semiconductor die to facilitate using shorter TSVs to couple bond pads to BEOL layers of the semiconductor die. Reducing the heights of the TSVs reduces the aspect ratios of the TSVs (e.g., to approximately 7:1 or less), and a reduction of the aspect ratios of the TSVs is expected to decrease the difficulty of forming the TSVs using certain materials (e.g., copper) and/or is expected to decrease the risk of encountering reliability issues, non-uniformity issues, and/or other types of issues. Therefore, the present technology is expected to facilitate forming reliable and/or more uniform interconnect structures (e.g., nano-vias, nano-TSVs) having physical dimensions that enable arranging bond pads at smaller pitches.

FIG. 1A is a partially schematic, cross-sectional side view of a semiconductor device 100 configured in accordance with various embodiments of the present technology, and FIG. 1B is an enlarged, detail view of a semiconductor die 110 of the semiconductor device 100 of FIG. 1A corresponding to the area of detail 1B shown in FIG. 1A. Referring to FIG. 1A, the semiconductor device 100 includes a semiconductor die 110 bonded to a carrier substrate 118. In some embodiments, the semiconductor die 110 can be a single semiconductor die in a wafer of such semiconductor dies. In these and other embodiments, the carrier substrate 118 can be a wafer, such as a silicon carrier wafer. Continuing with this example, the wafer of semiconductor dies can be bonded to the carrier wafer (e.g., using a wafer-to-wafer fusion bond or another suitable bond). In the illustrated embodiment, the semiconductor die 110 and the carrier substrate 118 are arranged front-to-front. Other arrangements (e.g., back-to-back, back-to-front, front-to-back) are of course possible and within the scope of the present technology.

In the illustrated embodiment, the semiconductor die 110 includes a plurality of layers and/or structures. More specifically, the semiconductor die 110 includes a first layer 101, a dielectric stack 106, and a stop layer 102 positioned between the first layer 101 and the dielectric stack 106. The semiconductor die 110 further includes (a) one or more intermediate layers 112 on a side of the first layer 101 opposite the stop layer 102, and (b) one or more back-end-of-line (BEOL) layers 116 coupled to a side of the intermediate layers 112 opposite the first layer 101. The one or more intermediate layers 112 can include one or more middle-of-line (MOL) layers, one or more BEOL layers, and/or one or more other layers of the semiconductor die 110. For the sake of example only, the one or more intermediate layers 112 are primarily shown and described as including or corresponding to one or more MOL layers of the semiconductor die 110.

In some embodiments, the first layer 101 can include or be formed of silicon or another suitable material. As a specific example, the semiconductor die 110 can be a DRAM die, such as a core DRAM die, a logic die, a CPU die, a GPU die, TPU die, etc. Continuing with this DRAM die example, the first layer 101 can be a silicon layer of the DRAM die.

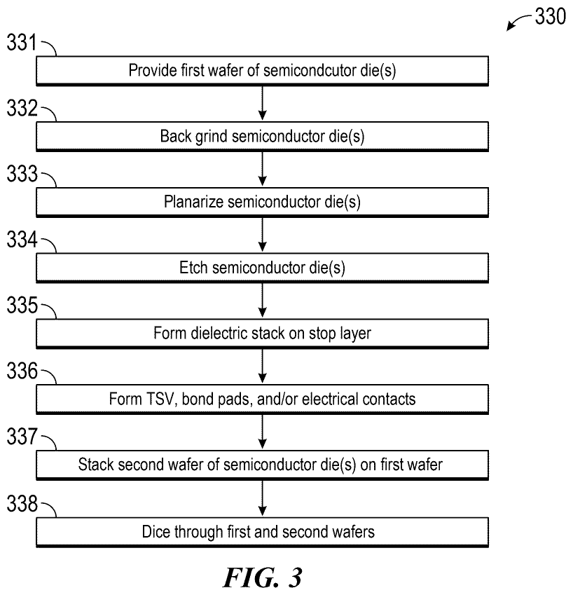

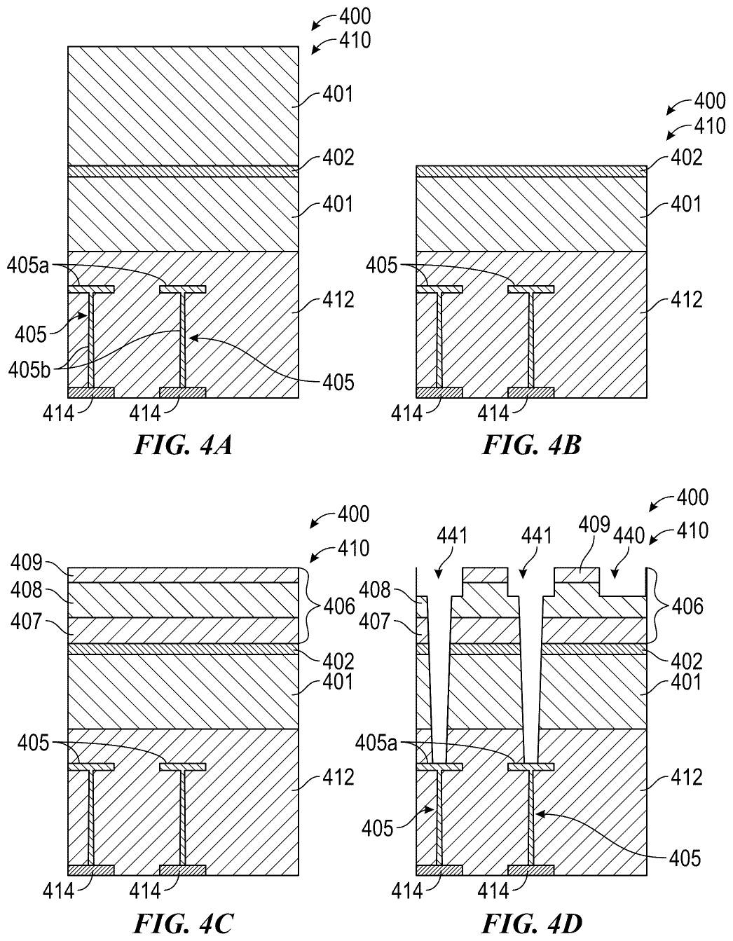

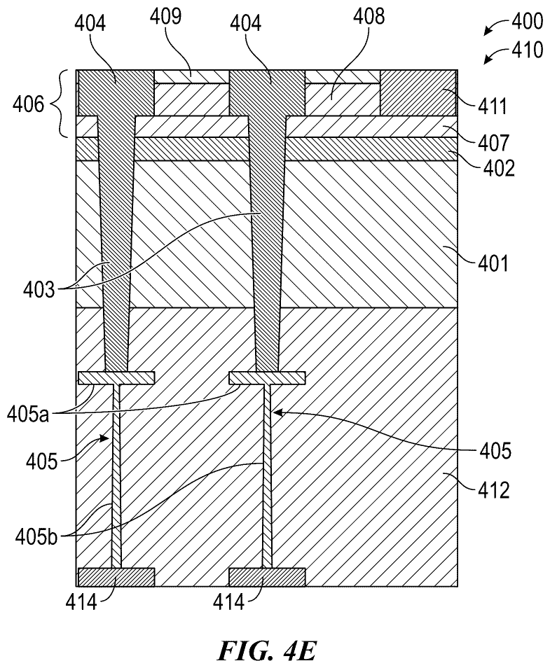

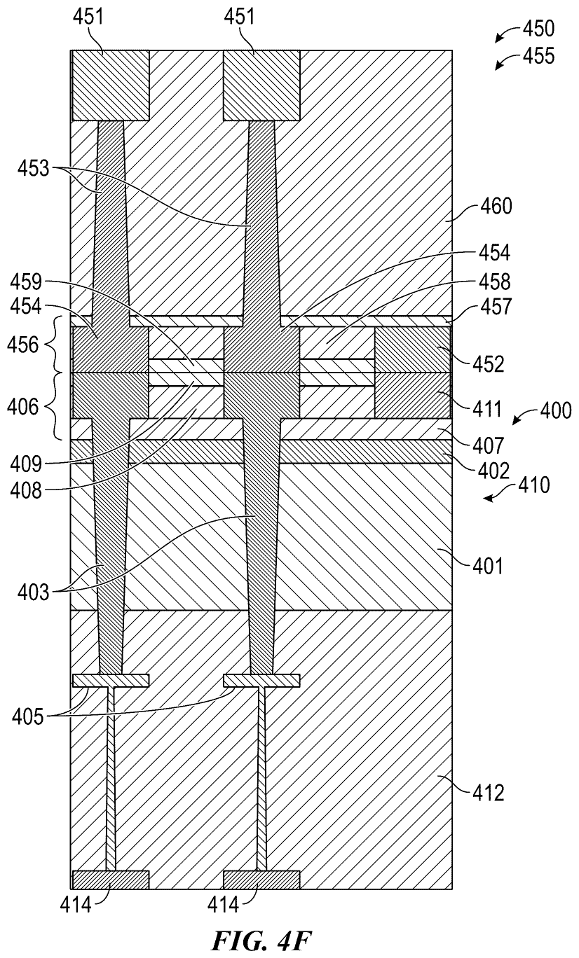

The stop layer 102 can include or be formed of silicon monoxide (SiO), silicon germanium (SiGe), carbon (C), or another suitable material. Additionally, or alternatively, the stop layer 102 can be formed in or on the first layer 101. For example, the stop layer 102 can be a layer buried or embedded within the first layer 101. As discussed in greater detail below with reference to FIGS. 3 and 4A, the stop layer 102 can be provided and used to achieve better total thickness variation (TTV) or semiconductor wafer planarity/uniformity by providing better control over a backside thinning process of the first layer 101 during fabrication. In some embodiments, the first layer 101 plus the stop layer 102 can be approximately 1.5 μm tall or thick. In some embodiments, the first layer 101 plus the stop layer 102 can be less than 1.5 μm thick, less than 1.4 μm thick, or less than 1.3 μm thick.

As best shown in FIG. 1B, the dielectric stack 106 of the semiconductor die 110 can include or be formed of a plurality of dielectric layers. In the illustrated embodiment, the dielectric stack 106 includes three layers 107-109. The layer 107 can include or be formed of silicon carbon nitride (SiCN) and/or another suitable material. The layer 108 can be an oxide layer, and/or can include or be formed of silicon monoxide (SiO) and/or another suitable material. In these and other embodiments, the layer 109 can include or be formed of SiCN and/or another suitable material.

The layers 107-109 are shown in FIGS. 1A and 1B with differing thicknesses. For example, the layer 108 is shown as being thicker than the layer 107 and the layer 109, and the layer 107 is shown as being thicker than the layer 109. As a specific example, the layer 107 can be approximately 0.2 μm in height, the layer 108 can be approximately 0.3 μm in height, and the layer 109 can be approximately 0.1 μm in height. Other thicknesses of one or more of the layers 107-109 are of course possible and within the scope of the present technology. Additionally, or alternatively, two or more of the layers 107-109 of the dielectric stack 106 can have uniform thicknesses in other embodiments of the present technology. In these and still other embodiments, the dielectric stack 106 can include a different number of layers (e.g., more than three layers or less than three layers).

The one or more intermediate layers 112 of the semiconductor die 110 can include various layers and/or structures. For example, in embodiments in which the semiconductor die 110 is or includes a DRAM die, the intermediate layers 112 can correspond to complementary metal-oxide semiconductor (CMOS) layers of a DRAM cell. In some embodiments, the intermediate layers 112 include one or more metal layers. For example, the intermediate layers 112 can include a metal layer formed of tungsten (W) or another suitable material, such as a metal layer in the MOL layers of the semiconductor die 110. The intermediate layers 112 can additionally, or alternatively, include one or more interconnect structures (e.g., formed of tungsten (W) or another suitable material). As discussed in greater detail below, one or more of the metal layers and/or one or more of the interconnect structures in the intermediate layers 112 can be used (e.g., leveraged, purposed, repurposed, designed) to form or provide at least part of landing pad structures 105 on which TSVs 103 of the semiconductor die 110 can land or terminate.

In embodiments in which an interconnect structure is used to form at least part of a landing pad structure 105, the interconnect structure can be approximately 1.625 μm to approximately 1.7 μm in height. In embodiments in which a metal layer is used to form at least part of a landing pad structure 105, the metal layer can be approximately 0.025 μm in height. Alternatively, as discussed in greater detail below with reference to FIGS. 3 and 4D, a thicker metal layer can be used in some embodiments to mitigate the risk of a dry etching process punching through the metal layer when forming the TSVs 103 in the semiconductor die 110. For example, a metal layer used to form at least part of a landing pad structure 105 can be approximately 0.1 μm in height in some embodiments. Although not shown so as to avoid unnecessarily obscuring aspects of the present technology, the intermediate layers 112 can include one or more layers and/or structures in addition to or in lieu of the metal layers and/or the metal interconnect structures used to form at least part of the landing pad structures 105.

The BEOL layers 116 of the semiconductor die 110 shown in FIGS. 1A and 1B include various dielectric layers, metal layers, and/or electrical contacts. The electrical contacts can provide bonding sites for die-to-package connections, such as between the semiconductor die 110 and the carrier substrate 118. As shown, the BEOL layers 116 include a metal layer 114 coupled to (e.g., a vertical component 105b, such as a metal interconnect, of) the intermediate layers 112. The metal layer 114 can be a metal layer M1 or another metal layer of the BEOL layers 116 in some embodiments of the present technology. Although not shown so as to avoid unnecessarily obscuring aspects of the present technology, the BEOL layers 116 can include one or more other layers and/or structures in addition to or in lieu of the metal layer 114, such as one or more layers included in the intermediate layers 112.

The semiconductor die 110 further includes various bond pads 104 and electrical contacts 111 at a backside of the semiconductor die 110 that are formed/disposed in or on the dielectric stack 106. In some embodiments, the bond pads 104 and the electrical contacts 111 are formed of copper (Cu). In other embodiments, one or more of the bond pads 104 and/or one or more of the electrical contacts 111 can be formed of another suitable material, such as tungsten or polysilicon.

The bond pads 104 and/or the electrical contacts 111 are arranged at the backside of the semiconductor die 110 at a given pitch. For example, in the illustrated embodiment, the bond pads 104 and/or the electrical contacts 111 are arranged such that they are uniformly spaced apart from one another by a specified distance. Referring to FIG. 1B as a specific example, the leftmost side of the leftmost bond pad 104 can be spaced approximately 1.6 μm from the leftmost side of the bond pad 104 illustrated in the middle of FIG. 1B. Additionally, or alternatively, the leftmost side of the bond pad 104 illustrated in the middle of FIG. 1B can be spaced approximately 1.6 μm from the leftmost side of the electrical contact 111. Continuing with this example, the widths of the bond pads 104 and/or the widths of the electrical contacts 111 can be less than 1.6 μm. For example, the widths of the bond pads 104 and/or the widths of the electrical contacts 111 can be approximately 0.5 μm to approximately 0.8 μm. Additionally, or alternatively, the heights of the bond pads 104 and/or the heights of the electrical contacts 111 can be approximately 0.4 μm.

In another embodiment, at least some of the bond pads 104 and/or the electrical contacts 111 are arranged at the backside of the semiconductor die 110 in such a way as to have a minimum/smallest pitch. Referring to FIG. 1B as a specific example, the leftmost side of the leftmost bond pad 104 illustrated in FIG. 1B can be spaced approximately 1.6 μm from the rightmost side of the bond pad 104 illustrated in the middle of FIG. 1B. Additionally, or alternatively, the leftmost side of of the bond pad 104 illustrated in the middle of FIG. 1B can be spaced approximately 1.6 μm from the rightmost side of the electrical contact 111.

Other pitches smaller or larger than 1.6 μm (e.g., 22.5 μm, 20 μm, 15 μm, 10 μm, 5 μm, 1 μm, 0.5 μm) are of course possible and within the scope of the present technology. Additionally, or alternatively, although the bond pads 104 and the electrical contacts 111 are illustrated as being uniformly spaced apart from one another, one or more of the bonds pads 104 and/or one or more of the electrical contacts 111 can be non-uniformly spaced apart from one another in other embodiments. In these and other embodiments, the widths of the bond pads 104 and/or the widths of the electrical contacts 111 can vary from one another, and/or can be larger than 0.8 μm or smaller than 0.5 μm in some embodiments. Additionally, or alternatively, the heights of the bond pads 104 and/or the heights of the electrical contacts 111 can vary from one another, and/or can be larger or smaller than 0.4 μm in various embodiments of the present technology.

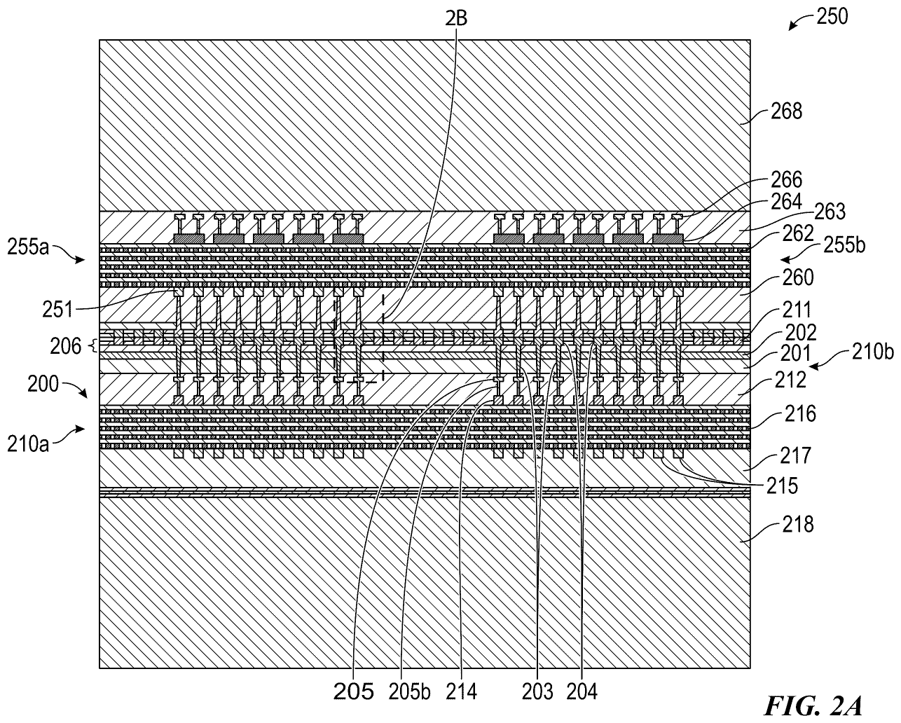

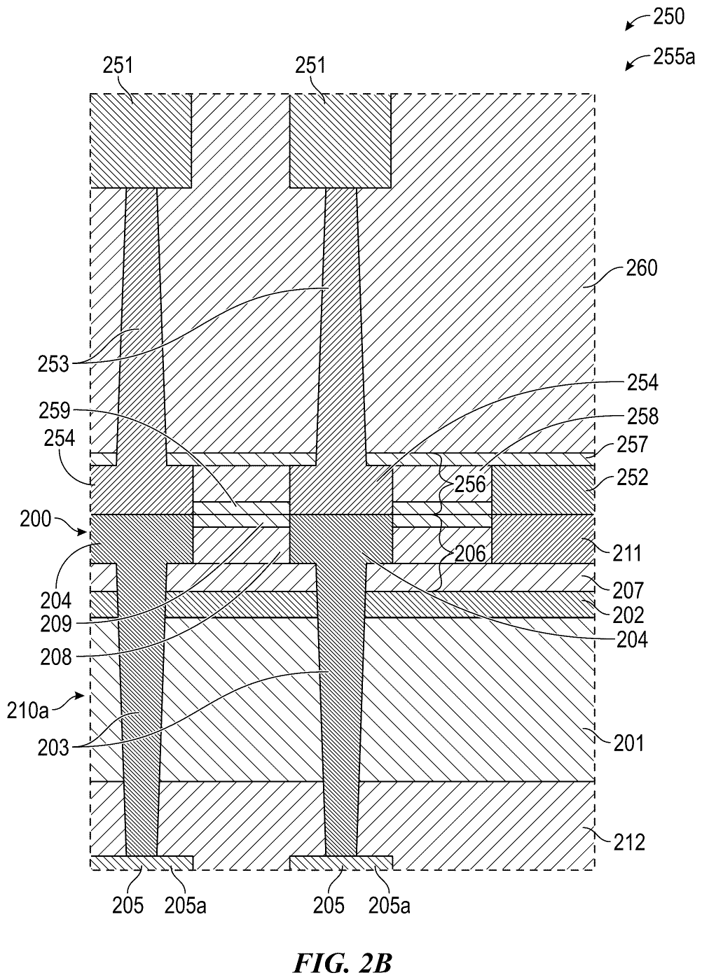

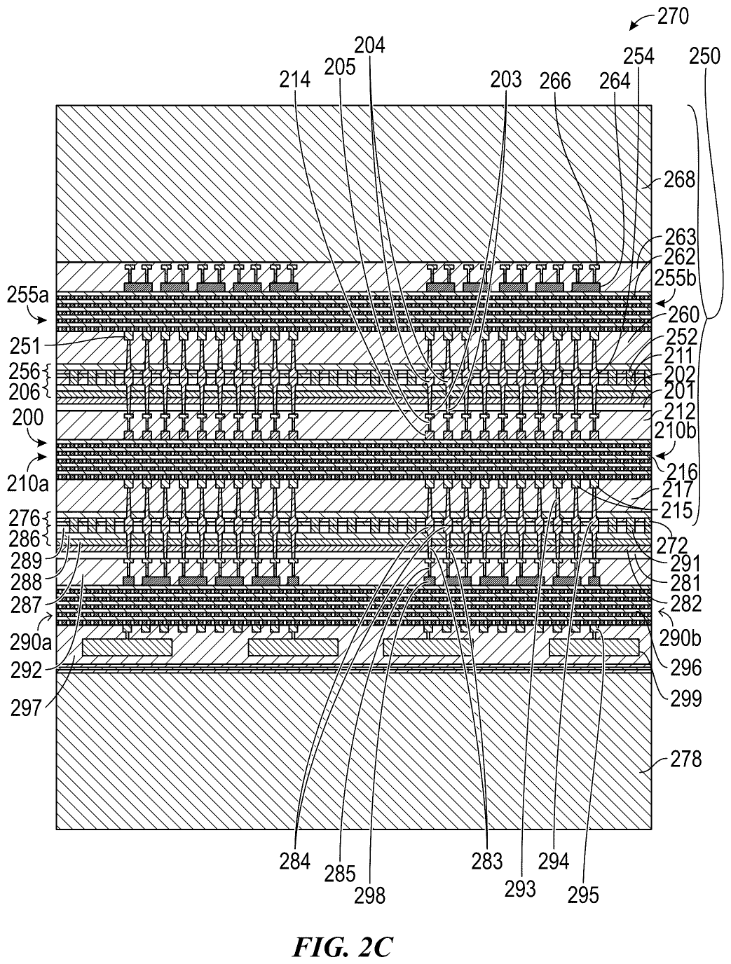

As discussed in greater detail below with reference to FIGS. 2A and 2B, the bond pads 104 and electrical contacts 111 provide locations on the backside of the semiconductor die 110 at which electrical connections can be formed for passing supply voltages, signals, etc. between the semiconductor die 110 and another structure (e.g., another semiconductor die) stacked on the semiconductor die 110. To facilitate passing supply voltages, signals, etc. through the bond pads 104, the semiconductor die 110 can include a plurality of TSVs 103 that are usable (in combination with the landing pad structures 105) for coupling corresponding bond pads 104 at the backside of the semiconductor die 110 to the BEOL layers 116 of the semiconductor die 110.

Physical dimensions of TSVs can depend at least in part on a pitch and/or widths of corresponding bond pads and/or electrical contacts. In the specific example above in which the bond pads 104 are arranged at a 1.6 μm pitch and are each approximately 0.5 μm to 0.8 μm in width, corresponding TSVs can be approximately 0.4 μm in width. Continuing with this example and assuming that the distance between a bottom surface of a bond pad 104 of the semiconductor die 110 and the metal layer 114 of the BEOL layers 116 is approximately 4 μm, a TSV that is approximately 0.4 μm in width and spans the entire distance between the bond pad 104 and the metal layer of the BEOL layers 116 would have an aspect ratio of height to width of about 10:1. As discussed above, forming a TSV with a 10:1 aspect ratio at this physical scale is extremely difficult (especially with copper) and frequently results in reliability issues (e.g., due to copper diffusion during TSV dry etching processes), non-uniformity issues (e.g., related to TSV depths during the TSV dry etching processes), and/or other issues. Therefore, as shown in FIGS. 1A and 1B, the semiconductor die 110 includes landing pad structures 105 that facilitate use of shorter TSVs, such as the TSVs 103.

More specifically, the semiconductor die 110 of FIGS. 1A and 1B includes a plurality of landing pad structures 105 that are formed in the intermediate layers 112 of the semiconductor die 110. For example, one or more of the landing pad structures 105 can be formed, at least in part, in or using a metal layer and/or one or more metal interconnects of or in the intermediate layers 112. As best shown in FIG. 1B, each of the landing pad structures 105 extends from (i) a location within the intermediate layers 112 to (ii) the metal layer 114 of the BEOL layers 116 (FIG. 1A) of the semiconductor die 110. In addition, each of the landing pad structures 105 provides a location in the intermediate layers 112 at which a corresponding one of the TSVs 103 can land or terminate. Thus, rather than extending an entire distance from one of the bond pads 104 at the backside of the semiconductor die 110 to the metal layer 114 in the BEOL layers 116, a corresponding one of the TSVs 103 in the illustrated embodiment merely extends from the bond pad 104 at the backside of the semiconductor die 110 to a corresponding one of the landing pad structures 105 in the intermediate layers 112 of the semiconductor die 110. In turn, the corresponding one of the landing pad structures 105 spans the remaining distance between (i) the location at which the TSV 103 terminates in the intermediate layers 112 and (ii) the metal layer 114 in the BEOL layers 116 of the semiconductor die 110.

As shown, each of the landing pad structures 105 includes a horizontal or landing pad component 105a (e.g., a metal layer, a landing pad) that is formed in the intermediate layers 112 of the semiconductor die 110 and that provides a location at which a corresponding one of the TSVs 103 can land or terminate. Each of the landing pad structures 105 further includes a vertical component 105b (e.g., a metal interconnect or other structure) that is formed in or at least in part by one or more of the intermediate layers 112 and that couples the corresponding landing pad component 105a to the metal layer 114 of the BEOL layers 116. The landing pad components 105a and/or the vertical components 105b of the landing pad structures 105 can include or be formed of tungsten (W) or another suitable material (e.g., copper, polysilicon, etc.). For example, at least a portion of the landing pad structures 105 (e.g., all or a subset of the landing pad components 105a and/or all or a subset of the vertical components 105b) can be formed in or by a W metal layer of the intermediate layers 112. Additionally, or alternatively, at least a portion of the landing pad structures 105 (e.g., all or a subset of the landing pad components 105a and/or all or a subset of the vertical components 105b) can be formed in or by a W metal interconnect of the intermediate layers 112. Other shapes and/or structures for the landing pad structures 105 than the shapes/structures shown in FIGS. 1A and 1B are of course possible and within the scope of the present technology.

Physical dimensions of the landing pad structures 105 can depend at least in part on the pitch and/or widths of the bond pads 104 and/or the electrical contacts 111. In the specific example above in which the bond pads 104 are arranged at a 1.6 μm pitch and are each approximately 0.5 μm to 0.8 μm in width, the landing pad components 105a of the corresponding landing pad structures 105 can be approximately 0.5 μm to 0.8 μm in width. Additionally, or alternatively, the landing pad components 105a can be approximately 0.025 μm to 0.1 μm in height. As a specific example, such as in embodiments in which the landing pad components 105a are at least partially formed in a W metal layer of the intermediate layers 112, the landing pad components 105a can be approximately 0.1 μm in height to mitigate the risk of a dry etching process punching through the landing pad components 105a when forming the TSVs 103 in the semiconductor die 110. In these and other embodiments, the vertical components 105b of the corresponding landing pad structures 105 can be approximately 0.085 μm in width. Additionally, or alternatively, the vertical components 105b of the landing pad structures 105 can be approximately 1.625 μm to approximately 1.7 μm in height, such as in embodiments in which the vertical components 105b are at least partially formed in or by a W metal layer or a W metal interconnect of or in the intermediate layers 112. Therefore, in this example, the landing pad structures 105 can be approximately 1.65 μm to approximately 1.8 μm tall. Other physical dimensions of the landing pad structures 105 are of course possible and within the scope of the present technology.

Because the TSVs 103 of the semiconductor die 110 span only the distances between the bond pads 104 and the corresponding ones of the landing pad structures 105 (rather than the distances between the bond pads 104 and the metal layer 114), the heights of the TSVs 103 that couple the bond pads 104 to the corresponding ones of the landing pad structures 105 are relatively small or short. Continuing with the specific example above in which (i) the bond pads 104 are arranged at a 1.6 μm pitch, (ii) the corresponding landing pad structures 105 are approximately 1.65 μm to approximately 1.8 μm in height, and (iii) the distance between one of the bond pads 104 and the metal layer 114 is approximately 4 μm, the heights of the TSVs 103 can be approximately 2.2 μm to approximately 2.35 μm (e.g., approximately 2.275 μm). Therefore, assuming that the TSVs 103 are approximately 0.4 μm in width, the aspect ratios of the heights of the TSVs 103 to their widths can be between approximately 5.5:1 and approximately 5.875:1 (e.g., approximately 5.7:1). As discussed above, TSVs having such aspect ratios can also be referred to herein as nano-TSVs. Other physical dimensions and/or aspect ratios of the TSVs 103 are of course possible and within the scope of the present technology. For example, the aspect ratios of heights of the TSVs 103 to their widths can include aspect ratios less than approximately 7:1, less than approximately 6:1, less than approximately 5:1, less than approximately 4:1, or smaller.

Therefore, by utilizing one or more metal layers and/or interconnect structures of or in the intermediate layers 112 of the semiconductor die 110 to provide landing pad structures 105 in the intermediate layers 112, the present technology facilitates using TSVs 103 with smaller dimensions and smaller aspect ratios. In turn, the formation of the TSVs 103 (e.g., especially using copper) is simplified and/or the risk of encountering reliability issues, non-uniformity issues, and/or other issues is reduced. Furthermore, in embodiments in which both the bond pads 104 and the TSVs 103 are formed of the same material (e.g., copper or another suitable material, such as tungsten, polysilicon, etc.), the bond pads 104 and the TSVs 103 can be formed together. Therefore, the present technology enables costs savings because a single etching step, a single metal deposition step, and/or a single chemical-mechanical polishing (CMP) step (as opposed to multiple etching steps, multiple metal deposition steps, and/or multiple CMP steps that would be required if the bond pads 104 and the TSVs 103 were formed of differing materials) can be used during fabrication to form the bonds pads 104 and the TSVs 103 at the same time. In other embodiments of the present technology, the bond pads 104 and/or the TSVs 103 can include or be formed of differing materials (e.g., copper, tungsten, polysilicon, etc.). Furthermore, the bonds pads 104 of the semiconductor die 110 can be considered part of the TSVs 103, especially in embodiments in which the bonds pads 104 and the TSVs 103 are formed with same material(s) and/or at the same time. Thus, a structure including a bond pad 104 and a corresponding TSV 103 can also be referred to herein as a dual damascene (DD) TSV. Given the physical dimensions of some of the TSVs 103 described in the examples above, a structure including a bond pad 104 and a corresponding TSV 103 can additionally, or alternatively, be referred to herein as a DD nano-TSV.

Although primarily shown and described above as being positioned in one or more MOL layers of the semiconductor die 110 in the embodiment illustrated in FIGS. 1A and 1B, the landing pad structures 105 (e.g., the landing pad components 105a and/or the vertical components 105b) can be positioned at or in (or formed at least part by) other intermediary layers of the semiconductor 110 between the bond pads 104 and the metal layer 114. For example, such other intermediary layers can include one or more BEOL layers (e.g., positioned above the metal layer 114). Additionally, or alternatively, such other intermediary layers can include one or more MOL layers such that a landing pad component 105a of a landing pad structures 105 is positioned closer to or further away from the bond pads 104 than the landing pad components 105a shown in FIGS. 1A and 1B. In turn, the TSVs 103 can span different distances between the bond pads 104 and the metal layer 114 and/or can terminate at other locations than the distances/locations shown in FIGS. 1A and 1B. As such, the TSVs 103 of these other embodiments of the present technology can have different aspect ratios than the TSVs 103 shown in FIGS. 1A and 1B.

FIG. 2A is a partially schematic, cross-sectional side view of another semiconductor device 250 configured in accordance with various embodiments of the present technology, and FIG. 2B is an enlarged, detail view of a stack of semiconductor dies (including semiconductor die 210a and semiconductor die 255a) of the semiconductor device 250 of FIG. 2A corresponding to the area of detail 2B shown in FIG. 2A. Referring to FIG. 2A, the semiconductor device 250 includes (i) a semiconductor device 200 having a plurality of semiconductor dies 210 (identified individually as first semiconductor die 210a and second semiconductor die 210b) bonded to a carrier substrate 218, and (ii) a plurality of semiconductor dies 255 (identified individually as first semiconductor die 255a and second semiconductor die 255b) stacked on the plurality of semiconductor dies 210. The first semiconductor die 210a and the second semiconductor die 210b can be semiconductor dies included in a first wafer of such semiconductor dies. In these and other embodiments, the carrier substrate 218 can be a wafer, such as a silicon carrier wafer. Continuing with this example, the first wafer of semiconductor dies 210 can be bonded to the carrier wafer (e.g., using a wafer-to-wafer fusion bond or another suitable bond). In the illustrated embodiment, the first and second semiconductor dies 210a and 210b and the carrier substrate 218 are arranged front-to-front. Other arrangements (e.g., back-to-back, back-to-front, front-to-back) are of course possible and within the scope of the present technology.

Additionally, or alternatively, the first semiconductor die 255a and the second semiconductor die 255b can be semiconductor dies included in a second wafer of such semiconductor dies. Continuing with this example, the second wafer of semiconductor dies 255 can be stacked on top of and/or bonded to the first wafer of semiconductor dies 210 (e.g., using a wafer-to-wafer hybrid bond or another suitable bond). More specifically, the second wafer can be stacked on top of the first wafer such that (a) the first semiconductor die 255a of the second wafer is stacked on top of the first semiconductor die 210a of the first wafer, and (b) the second semiconductor die 255b of the second wafer is stacked on top of the second semiconductor die 210b of the first wafer. As discussed in greater detail below, electrical contacts 252 and/or bond pads 254 of the first and second semiconductor dies 255a and 255b can be aligned with and electrically coupled to electrical contacts 211 and bond pads 204 of the first and second semiconductor dies 210a and 210b, respectively. In the illustrated embodiment, the first and second semiconductor dies 255a and 255b are stacked on the first and second semiconductor dies 210a and 210b such that front sides of the first and second semiconductor dies 255a and 255b are facing and are coupled to backsides of the first and second semiconductor dies 210a and 210b, respectively. Other arrangements (e.g., back-to-back, back-to-front, front-to-front) of the semiconductor dies 255 and 210 are of course possible and within the scope of the present technology.

In some embodiments, the first semiconductor die 210a, the second semiconductor die 210b, the first semiconductor die 255a, and/or the second semiconductor die 255b can be memory dies, such as DRAM dies. As a specific example, the first semiconductor die 210a and/or the second semiconductor die 210b can be core DRAM dies. Continuing with this example, the first semiconductor die 255a and/or the second semiconductor die 255b can be top DRAM dies that are stacked on the respective core DRAM dies 210a and/or 210b.

The first semiconductor die 210a and/or the second semiconductor die 210b can be identical or at least generally similar to the semiconductor die 110 of FIGS. 1A and 1B. For example, referring to FIGS. 2A and 2B, the first semiconductor die 210a and the second semiconductor die 210b can include (i) a first layer 201, (ii) a dielectric stack 206 formed of a plurality of layers (e.g., layers 207-209), and (iii) a stop layer 202 positioned between the first layer 201 and the dielectric stack 206. The first semiconductor die 210a and the second semiconductor die 210b can further include intermediate layers 212 and BEOL layers 216. The intermediate layers 212 can include one or more MOL layers and/or one or more BEOL layers of the first semiconductor die 210a and/or the second semiconductor die 210b. The first semiconductor die 210a and the second semiconductor die 210b can include electrical contacts 211, bond pads 204, landing pad structures 205 formed in the intermediate layers 212, and corresponding TSVs 203 (e.g., nano-TSVs) that couple respective ones of the bond pads 204 to respective ones of the landing pad structures 205. The landing pad structures 205 can include landing pad components 205a (FIG. 2B) and/or vertical components 205b (FIG. 2A) similar to the landing pad structures 105 of FIGS. 1A and 1B. The bond pads 204 can be coupled to a metal layer 214 of the BEOL layers 216 through corresponding TSVs 203 and landing pad structures 205. The bond pads 204, the electrical contacts 211, the TSVs 203, and/or the landing pad structures 205 can include or be formed of copper, tungsten, polysilicon, and/or another suitable material. Structures formed by the bond pads 204 and the TSVs 203 can also be referred to herein as dual damascene (DD) TSVs and/or as DD nano-TSVs. The first semiconductor die 210a and the second semiconductor die 210b are illustrated in FIG. 2A with additional interconnect structures 215 and other layers 217 included in and/or coupled to the BEOL layers 216. The interconnect structures 215 can be electrical contacts or pads and/or can include or be formed of aluminum (Al) or another suitable material.

The first semiconductor die 255a and/or the second semiconductor die 255b can include several components generally similar to select components of the first and second semiconductor dies 210a and 210b. For example, as best shown in FIG. 2B, the first semiconductor die 255a and/or the second semiconductor die 255b can include a dielectric stack 256. The dielectric stack 256 can include or be formed of a plurality of dielectric layers. In the illustrated embodiment, the dielectric stack 256 includes three layers 257-259. The layer 257 can include or be formed of silicon carbon nitride (SiCN) and/or another suitable material. The layer 258 can be an oxide layer, and/or can include or be formed of silicon monoxide (SiO) and/or another suitable material. In these and other embodiments, the layer 259 of the dielectric stack 256 can include or be formed of SiCN and/or another suitable material.

The layers 257-259 are shown in FIGS. 2A and 2B with various thicknesses. For example, the layer 258 is shown as being thicker than the layer 257 and the layer 259. As a specific example, the layer 257 can be approximately 0.1 μm in height, the layer 258 can be approximately 0.3 μm in height, and the layer 259 can be approximately 0.1 μm in height. Other thicknesses of one or more of the layers 257-259 are of course possible and within the scope of the present technology. Additionally, or alternatively, the layers 257-259 of the dielectric stack 256 can have uniform thicknesses in other embodiments of the present technology, and/or each of the layers 257-259 can have a thickness that differs from the thickness of the other ones of the layers 257-259. In these and still other embodiments, the dielectric stack 256 can include a different number of layers (e.g., more than three layers or less than three layers).

The first semiconductor die 255a and the second semiconductor die 255b can further include bond pads 254 and electrical contacts 252 at a front side of the first and second semiconductor dies 255a and 255b that are formed or disposed in or on the dielectric stack 256. In some embodiments, the bond pads 254 and/or the electrical contacts 252 are formed of copper (Cu). In other embodiments, one or more of the bond pads 254 and/or one or more of the electrical contacts 252 can be formed of another suitable material, such as tungsten or polysilicon.

The bond pads 254 and/or the electrical contacts 252 are arranged at the front side of the semiconductor dies 255a and 255b at a given pitch. For example, in the illustrated embodiment, the bond pads 254 and/or the electrical contacts 252 can be arranged such that they are uniformly spaced apart from one another by a specified distance. Additionally, or alternatively, the bond pads 254 and/or the electrical contacts 252 can be arranged with a pitch that corresponds to or matches the pitch of corresponding bond pads 204 and/or electrical contacts 211 of the semiconductor dies 210a and 210b. Referring to FIG. 2B as a specific example and assuming that the pitch of the bond pads 204 and the electrical contacts 211 of the semiconductor dies 210a and 210b is 1.6 μm, the leftmost side of the leftmost bond pad 254 can be spaced approximately 1.6 μm from the leftmost side of the bond pad 254 illustrated in the middle of FIG. 2B. Additionally, or alternatively, the leftmost side of the bond pad 254 illustrated in the middle of FIG. 2B can be spaced approximately 1.6 μm from the leftmost side of the electrical contact 252. Continuing with this example, the widths of the bond pads 254 and/or the widths of the electrical contacts 252 can be less than 1.6 μm. For example, the widths of the bond pads 254 and/or the widths of the electrical contacts 252 can be approximately 0.5 μm to approximately 0.8 μm. Additionally, or alternatively, the heights of the bond pads 254 and/or the heights of the electrical contacts 252 can be approximately 0.4 μm.

In other embodiments, at least some of the bond pads 254 and/or the electrical contacts 252 can be arranged at the front side of the semiconductor dies 255a and 255b in such a way as to have a minimum or smallest pitch. The bond pads 254 and/or the electrical contacts 252 can be arranged with a pitch that corresponds to or matches the pitch of corresponding bond pads 204 and/or electrical contacts 211 of the semiconductor dies 210a and 210b. Referring to FIG. 2B as a specific example and assuming that the pitch of at least some of the bond pads 204 and the electrical contacts 211 of the semiconductor dies 210a and 210b is 1.6 μm, the leftmost side of the at least some of the leftmost bond pad 254 can be spaced approximately 1.6 μm from the rightmost side of at least some of the bond pad 254 illustrated in the middle of FIG. 2B. Additionally, or alternatively, the leftmost side of at least some of the bond pad 254 illustrated in the middle of FIG. 2B can be spaced approximately 1.6 μm from the rightmost side of at least some of the electrical contact 252.

Other pitches smaller or larger than 1.6 μm (e.g., 22.5 μm, 20 μm, 15 μm, 10 μm, 5 μm, 1 μm, 0.5 μm) are of course possible and within the scope of the present technology. Additionally, or alternatively, although the bond pads 254 and the electrical contacts 252 are illustrated as being uniformly spaced apart from one another, one or more of the bonds pads 254 and/or one or more of the electrical contacts 252 can be non-uniformly spaced apart from one another in other embodiments. In these and other embodiments, the widths of the bond pads 254 and/or the widths of the electrical contacts 252 can vary from one another, and/or can be larger than 0.8 μm or smaller than 0.5 μm in some embodiments. Additionally, or alternatively, the heights of the bond pads 254 and/or the heights of the electrical contacts 252 can vary from one another, and/or can be larger or smaller than 0.4 μm in various embodiments of the present technology.

The bond pads 254 and the electrical contacts 252 provide locations on the front side of the first and second semiconductor dies 255a and 255b at which electrical connections can be formed for passing supply voltages, signals, etc. between the first and second semiconductor dies 255a and 255b and the first and second semiconductor dies 210a and 210b, respectively. To facilitate passing supply voltages, signals, etc. through the bond pads 254, the first and second semiconductor dies 255a and 255b can include a plurality of vias 253 (e.g., interconnects, vertical interconnects) that are used for coupling (a) corresponding bond pads 254 at the front side of the first and second semiconductor dies 255a and 255b to (b) corresponding interconnect structures 251 (FIG. 2B), through one or more layers 260 of the first and second semiconductor dies 255a and 255b. The interconnect structures 251 can be included in or coupled to BEOL layers 262 (FIG. 2A) of the first and second semiconductor dies 255a and 255b. In some embodiments, the interconnect structures 251 can be electrical contacts or pads and/or can include or be formed of aluminum (Al) or another suitable material.

Physical dimensions of the vias 253 can depend at least in part on the pitch and/or widths of the bond pads 254 and/or the electrical contacts 252. In the specific example above in which the bond pads 254 are arranged at a 1.6 μm pitch and are each approximately 0.5 μm to 0.8 μm in width, each of the corresponding vias 253 can be approximately 0.4 μm in width. Additionally, or alternatively, a distance between the bond pads 254 and the interconnect structures 251 can be approximately 2.2 μm such that the vias 253 are approximately 2.2 μm in height. Thus, continuing with this example, the vias 253 can have aspects ratios of height to widths of approximately 5.5:1. The vias 253 can include or be formed of copper and/or another suitable material, such as tungsten or polysilicon. Furthermore, the bonds pads 254 of the semiconductor dies 255a and/or 255b can be considered part of the vias 253, especially in embodiments in which the bonds pads 254 and the vias 253 are formed with same material(s) and/or at the same time. Thus, a structure including a bond pad 254 and a corresponding via 253 can also be referred to herein as a dual damascene (DD) via and/or as a DD nano-via. As used herein, the term nano-via refers to a via having an aspect ratio of height to width of less than or equal to 7:1, such as less than or equal to 6:1, less than or equal to 5:1, less than or equal to 4:1, or smaller.

As shown in FIG. 2A, the first and second semiconductor dies 255a and 255b can further include a metal layer 264 (e.g., a metal layer M1) at a side of the BEOL layers 262 opposite the interconnect structures 251. The first and second semiconductor dies 255a and 255b additionally include (a) layers 263, (b) interconnect structures 266 formed in the layers 263, and (c) a layer 268 at backsides of the first and second semiconductor dies 255a and 255b. In some embodiments, the layers 263 can be or include MOL layers and/or complementary metal-oxide semiconductor (CMOS) layers of a DRAM cell. In these and other embodiments, the interconnect structures 266 can be landing pad structures (e.g., similar to the landing pad structures 105 (FIGS. 1A and 1B) and/or the landing pad structures 205) or other TSVs, contact pads, etc. Additionally, or alternatively, the layer 268 can include or be formed of silicon or another suitable material. As a specific example, when the first and second semiconductor dies 255a and/or 255b are DRAM dies, the layer 268 can be or include a silicon layer of the DRAM dies.

As discussed above, the first and second semiconductor dies 255a and 255b are stacked on the first and second semiconductor dies 210a and 210b, respectively, such that the bond pads 254 and the electrical contacts 252 of the semiconductor dies 255a and 255b are aligned with the bond pads 204 and the electrical contacts 211 of the semiconductor dies 210a and 210b, respectively. More specifically, as best shown in FIG. 2B, dual damascene (DD) via structures (each including a bond pad 254 and a corresponding via 253) of the first and second semiconductor dies 255a and 255b are aligned with DD TSV or DD nano-TSV structures (each including a bond pad 204 and a corresponding TSV 203) of the first and second semiconductor dies 210a and 210b, respectively. The bonds pads 254 can be coupled to the bond pads 204. In this manner, supply voltages, signals, etc. can be passed (e.g., between the BEOL layers 216 of the first and second semiconductor dies 210a and 210b and the BEOL layers 262 of the first and second semiconductor dies 255a and 255b, respectively,) along or through the metal layer 214, one or more landing pad structures 205, one or more corresponding TSVs 203, one or more corresponding bond pads 204, one or more corresponding bond pads 254, one or more corresponding vias 253, and the interconnect structures 251. In these and other embodiments, electrical contacts 252 of the first and second semiconductor dies 255a and 255b can be aligned with and coupled to electrical contacts 211 of the first and second semiconductor dies 210a and 210b, respectively. As such, supply voltages, signals, etc. can be passed between the semiconductor dies 210a and 210b and the semiconductor dies 255a and 255b, respectively, via the electrical contacts 211 and the electrical contacts 252.

FIG. 2C is a partially schematic view of the semiconductor device 250 of FIGS. 2A and 2B incorporated into a larger system 270 in accordance with various embodiments of the present technology. More specifically, FIG. 2C shows the semiconductor device 250 stacked on a plurality of semiconductor dies (identified individually as first semiconductor die 290a and second semiconductor die 290b) after (i) removal of the carrier substrate 218 (FIG. 2A), (ii) formation of a dielectric stack 276 at a front side of the first semiconductor die 210a and the second semiconductor die 210b, (iii) formation of vias 293 (e.g., interconnects, vertical interconnects) in the layers 217 and the dielectric stack 276, and (iv) formation/disposal of bond pads 294 and electrical contacts 272 in or on the dielectric stack 276 at the front side of the first semiconductor die 210a and the second semiconductor die 210b.

The dielectric stack 276 can be generally similar to the dielectric stack 206 and/or the dielectric stack 256. For example, the dielectric stack 276 can include or be formed of a plurality of dielectric layers. In the illustrated embodiment, the dielectric stack 276 includes three layers. One or more of the layers of the dielectric stack 276 can include or be formed of silicon carbon nitride (SiCN), silicon monoxide (Si), and/or one or more other suitable materials. Additionally, or alternatively, at least one of the layers of the dielectric stack 276 can be an oxide layer. The layers of the dielectric stack 276 are shown in FIG. 2C with various thicknesses. Other thicknesses of one or more of the layers of the dielectric stack 276 are of course possible and within the scope of the present technology. Additionally, or alternatively, the layers of the dielectric stack 276 can have uniform thicknesses in other embodiments of the present technology, and/or each of the layers of the dielectric stack 276 can have a thickness that differs from the thickness of the other ones of the layers of the dielectric stack 276. In these and still other embodiments, the dielectric stack 276 can include a different number of layers (e.g., more than three layers or less than three layers).

In some embodiments, the bond pads 294 and electrical contacts 272 can be formed of copper (Cu). In other embodiments, one or more of the bond pads 294 and/or one or more of the electrical contacts 272 can be formed of another suitable material, such as tungsten or polysilicon. The bond pads 294 and/or the electrical contacts 272 are arranged at the front side of the first and second semiconductor dies 210a and 210b at a given pitch. For example, in the illustrated embodiment, the bond pads 294 and/or the electrical contacts 272 of each of the semiconductor dies 210a and 210b can be arranged such that they are uniformly spaced apart from one another by a specified distance. Additionally, or alternatively, the bond pads 294 and/or the electrical contacts 272 can be arranged with a pitch that corresponds to or matches the pitch of corresponding bond pads 284 and/or electrical contacts 291 of the first and second semiconductor dies 290a and 290b. As a specific example, assuming that the pitch of at least some of the bond pads 284 and the electrical contacts 291 of the first and second semiconductor dies 290a and 290b is 1.6 μm, the pitch of corresponding bond pads 294 and electrical contacts 272 of the first and second semiconductor dies 210a and 210b can be 1.6 μm. For example, and a leftmost side of a bond pad 294 can be spaced approximately 1.6 μm from a leftmost side of an immediately adjacent bond pad 294. Additionally, or alternatively, for a bond pad 294 positioned immediately adjacent an electrical contact 272, the leftmost side of the bond pad 294 can be spaced approximately 1.6 μm from the leftmost side of the electrical contact 272. Continuing with this example, the widths of the bond pads 294 and/or the widths of the electrical contacts 272 can be less than 1.6 μm. For example, the widths of the bond pads 294 and/or the widths of the electrical contacts 272 can be approximately 0.5 μm to approximately 0.8 μm. Additionally, or alternatively, the heights of the bond pads 294 and/or the heights of the electrical contacts 272 can be approximately 0.4 μm.

In other embodiments, at least some of the bond pads 294 and/or the electrical contacts 272 can be arranged at the front side of the semiconductor dies 210a and 210b in such a way as to have a minimum or smallest pitch. The bond pads 294 and/or the electrical contacts 272 can be arranged with a pitch that corresponds to or matches the pitch of corresponding bond pads 284 and/or electrical contacts 291 of the first and second semiconductor dies 290a and 290b. As a specific example, assuming that the pitch of at least some of the bond pads 284 and the electrical contacts 291 of the first and second semiconductor dies 290a and 290b is 1.6 μm, the leftmost side of a bond pad 294 can be spaced approximately 1.6 μm from the rightmost side of an immediately adjacent bond pad 294. Additionally, or alternatively, the leftmost side of a bond pad 294 positioned immediately adjacent an electrical contact 272 can be spaced approximately 1.6 μm from the rightmost side of the electrical contact 272.

Other pitches smaller or larger than 1.6 μm (e.g., 22.5 μm, 20 μm, 15 μm, 10 μm, 5 μm, 1 μm, 0.5 μm) are of course possible and within the scope of the present technology. Additionally, or alternatively, although the bond pads 294 and the electrical contacts 272 are illustrated as being uniformly spaced apart from one another, one or more of the bonds pads 294 and/or one or more of the electrical contacts 272 can be non-uniformly spaced apart from one another in other embodiments. In these and other embodiments, the widths of the bond pads 294 and/or the widths of the electrical contacts 272 can vary from one another, and/or can be larger than 0.8 μm or smaller than 0.5 μm in some embodiments. Additionally, or alternatively, the heights of the bond pads 294 and/or the heights of the electrical contacts 272 can vary from one another, and/or can be larger or smaller than 0.4 μm in various embodiments of the present technology.

The bond pads 294 and the electrical contacts 272 provide locations on the front side of the first and second semiconductor dies 210a and 210b at which electrical connections can be formed for passing supply voltages, signals, etc. between the first and second semiconductor dies 290a and 290b and the first and second semiconductor dies 210a and 210b, respectively. To facilitate passing supply voltages, signals, etc. through the bond pads 294, the vias 293 can be used to couple (a) corresponding bond pads 294 at the front side of the first and second semiconductor dies 210a and 210b to (b) corresponding ones of the interconnect structures 215, through the layers 217 of the first and second semiconductor dies 210a and 210b. The interconnect structures 215 can be included in or coupled to the BEOL layers 216 of the first and second semiconductor dies 210a and 210b. As discussed above, the interconnect structures 215 can be electrical contacts or pads and/or can include or be formed of aluminum (Al) or another suitable material.

Physical dimensions of the vias 293 can depend at least in part on the pitch and/or widths of the bond pads 294 and/or the electrical contacts 272. In the specific example above in which the bond pads 294 are arranged at a 1.6 μm pitch and are each approximately 0.5 μm to 0.8 μm in width, each of the corresponding vias 293 can be approximately 0.4 μm in width. Additionally, or alternatively, a distance between the bond pads 294 and the interconnect structures 215 can be approximately 2.2 μm such that the vias 293 are approximately 2.2 μm in height. Thus, continuing with this example, the vias 293 can have aspects ratios of height to widths of approximately 5.5:1, and can also be referred to herein as nano-vias. The vias 293 can include or be formed of copper and/or another suitable material, such as tungsten or polysilicon. Furthermore, the bonds pads 294 of the semiconductor dies 210a and/or 210b can be considered part of the vias 293, especially in embodiments in which the bonds pads 294 and the vias 293 are formed with same material(s) and/or at the same time. Thus, a structure including a bond pad 294 and a corresponding via 293 can also be referred to herein as a dual damascene (DD) via and/or as a DD nano-via.

Referring now to the first and second semiconductor dies 290a and 290b, the first semiconductor die 290a can be a logic die, a CPU die, a GPU die, a TPU die, or another suitable type of die. Additionally, or alternatively, the second semiconductor die 290b can be a logic die, a GPU die, a TPU die, or another suitable type of die. The first and second semiconductor dies 290a and 290b can be semiconductor dies included in a third wafer of such semiconductor dies. The third wafer can be bonded to a carrier substrate 278. The carrier substrate 278 can be a wafer, such as a silicon carrier wafer. Continuing with this example, the third wafer can be bonded to the carrier wafer (e.g., using a wafer-to-wafer fusion bond and/or another suitable bond). In the illustrated embodiment, the first and second semiconductor dies 290a and 290b and the carrier substrate 278 are arranged front-to-front. Other arrangements (e.g., back-to-back, back-to-front, front-to-back) are of course possible and within the scope of the present technology.

As discussed above, the first semiconductor die 210a and the second semiconductor die 210b can be semiconductor dies included in a first wafer of such semiconductor dies. Continuing with this example, the first wafer that includes the first and second semiconductor dies 210a and 210b can be stacked on top of and/or bonded to the third wafer that includes the semiconductor dies 290 and 290b (e.g., using a wafer-to-wafer hybrid bond or another suitable bond). More specifically, the first wafer can be stacked on top of the third wafer such that (a) the first semiconductor die 210a of the first wafer is stacked on top of the first semiconductor die 290a of the third wafer, and (b) the second semiconductor die 210b of the first wafer is stacked on top of the second semiconductor die 290b of the third wafer.

Alternatively, the first semiconductor die 210a and the second semiconductor die 210b can be diced or singulated prior to stacking the first and second semiconductor dies 210a and 210b on the first and second semiconductor dies 290a and 290b, respectively. Continuing with this example, the first and second semiconductor dies 210a and 210b can be diced and stacked on top of and/or bonded to the first and second semiconductor dies 290a and 290b, respectively, (e.g., using chip-to-wafer hybrid bonds or one or more other suitable bonds). At the time of stacking, the first and second semiconductor dies 290a and 290b can be included in the third wafer. Alternatively, the first and second semiconductor dies 290a and 290b can be diced or singulated prior to stacking the first and second semiconductor die 210a and 210b on the first and second semiconductor dies 290a and 290b. The first semiconductor die 210a can be stacked on top of the first semiconductor die 290a at a same timing as or at a different timing from when the second semiconductor die 210b is stacked on top of the second semiconductor die 290b.

As discussed in greater detail below, the electrical contacts 272 and/or the bond pads 294 of the first and second semiconductor dies 210a and 210b can be aligned with and electrically coupled to electrical contacts 291 and bond pads 284 of the first and second semiconductor dies 290a and 290b, respectively. In the illustrated embodiment, the first and second semiconductor dies 210a and 210b are stacked on the first and second semiconductor dies 290a and 290b such that front sides of the first and second semiconductor dies 210a and 210b are facing and are coupled to backsides of the first and second semiconductor dies 290a and 290b, respectively. Other arrangements (e.g., back-to-back, back-to-front, front-to-front) of the semiconductor dies 210 and 290 are of course possible and within the scope of the present technology.

The first semiconductor die 290a and/or the second semiconductor die 290b can include several components generally similar to select components of the first and second semiconductor dies 210a and 210b. For example, the first semiconductor die 290a and/or the second semiconductor die 290b can include a dielectric stack 286. The dielectric stack 286 can include or be formed of a plurality of dielectric layers. In the illustrated embodiment, the dielectric stack 286 includes three layers 287-289. The layer 287 can include or be formed of silicon carbon nitride (SiCN) and/or another suitable material. The layer 288 can be an oxide layer, and/or can include or be formed of silicon monoxide (SiO) and/or another suitable material. In these and other embodiments, the layer 289 of the dielectric stack 286 can include or be formed of SiCN and/or another suitable material.

The layers 287-289 are shown in FIG. 2C with various thicknesses. For example, the layer 288 is shown as being thicker than the layer 287 and the layer 289. As a specific example, the layer 287 can be approximately 0.1 μm in height, the layer 288 can be approximately 0.3 μm in height, and the layer 289 can be approximately 0.1 μm in height. Other thicknesses of one or more of the layers 287-289 are of course possible and within the scope of the present technology. Additionally, or alternatively, the layers 287-289 of the dielectric stack 286 can have uniform thicknesses in other embodiments of the present technology, and/or each of the layers 287-289 can have a thickness that differs from the thickness of the other ones of the layers 287-289. In these and still other embodiments, the dielectric stack 286 can include a different number of layers (e.g., more than three layers or less than three layers).

The first semiconductor die 290a and the second semiconductor die 290b can further include (i) a first layer 281 and (ii) a stop layer 282 positioned between the first layer 281 and the dielectric stack 286. The first layer 281 can include or be formed of silicon or another suitable material. As a specific example, the first layer 281 can be a silicon layer of logic die, GPU die, CPU die, TCU die, or another suitable type of die.

The first semiconductor die 290a and the second semiconductor die 290b can include intermediate layers 292 and BEOL layers 296. The intermediate layers 292 can include one or more MOL layers and/or one or more BEOL layers of the first semiconductor die 290a and/or the second semiconductor die 290b. The first semiconductor die 290a and the second semiconductor die 290b can include electrical contacts 291, bond pads 284, landing pad structures 285 formed in the intermediate layers 212, and corresponding TSVs 283 (e.g., nano-TSVs) that couple respective ones of the bond pads 284 to respective ones of the landing pad structures 285. The landing pad structures 285 can include landing pad components and/or vertical components similar to the landing pad structures 105 of FIGS. 1A and 1B and/or to the landing pad structures 205 of the first and second semiconductor dies 210a and 210b. As discussed in greater detail below, the bond pads 284 can be coupled to a metal layer 298 of the BEOL layers 296 through corresponding TSVs 283 and landing pad structures 285. The bond pads 284, the electrical contacts 291, the TSVs 283, and/or the landing pad structures 285 can include or be formed of copper, tungsten, polysilicon, and/or another suitable material. Structures formed by the bond pads 284 and the TSVs 283 can also be referred to herein as dual damascene (DD) TSVs and/or as DD nano-TSVs. The first semiconductor die 290a and the second semiconductor die 290b are illustrated in FIG. 2C with additional interconnects 295, redistribution structures 299 (e.g., redistribution layers, inline redistribution layers), and other layers 297 included in and/or coupled to the BEOL layers 296 on a side of the BEOL layers 296 opposite the metal layer 298. The interconnects 295 can be electrical contacts or pads. Additionally, or alternatively, the interconnects 295 and/or the redistribution structures 299 can include or be formed of aluminum (Al) or another suitable material. As shown in FIG. 2C, some of the interconnects 295 can be coupled to one or more of the redistribution structures 299, such as through via structures or other electrical contacts/structures.

The bond pads 284 and the electrical contacts 291 at the back side of the first and second semiconductor dies 290a and 290b can be formed or disposed in or on the dielectric stack 286. The bond pads 284 and/or the electrical contacts 291 are arranged at a given pitch. For example, in the illustrated embodiment, the bond pads 284 and/or the electrical contacts 291 can be arranged such that they are uniformly spaced apart from one another in each of the semiconductor dies 290a and 290b by a specified distance. Additionally, or alternatively, the bond pads 284 and/or the electrical contacts 291 can be arranged with a pitch that corresponds to or matches the pitch of corresponding ones of the bond pads 294 and/or the electrical contacts 272 of the semiconductor dies 210a and 210b. As a specific example, assuming that the pitch of the bond pads 294 and the electrical contacts 272 of the semiconductor dies 210a and 210b is 1.6 μm, the leftmost side of a bond pad 284 can be spaced approximately 1.6 μm from the leftmost side of an immediately adjacent bond pad 284. Additionally, or alternatively, the leftmost side of a bond pad 284 positioned immediately adjacent an electric contact 291 can be spaced approximately 1.6 μm from the leftmost side of the electrical contact 291. Continuing with this example, the widths of the bond pads 284 and/or the widths of the electrical contacts 291 can be less than 1.6 μm. For example, the widths of the bond pads 284 and/or the widths of the electrical contacts 291 can be approximately 0.5 μm to approximately 0.8 μm. Additionally, or alternatively, the heights of the bond pads 284 and/or the heights of the electrical contacts 291 can be approximately 0.4 μm.

In other embodiments, at least some of the bond pads 284 and/or the electrical contacts 291 can be arranged at the back side of the semiconductor dies 290a and 290b in such a way as to have a minimum or smallest pitch. The bond pads 284 and/or the electrical contacts 291 can be arranged with a pitch that corresponds to or matches the pitch of corresponding bond pads 294 and/or electrical contacts 272 of the semiconductor dies 210a and 210b. As a specific example, assuming that the pitch of at least some of the bond pads 294 and the electrical contacts 272 of the semiconductor dies 210a and 210b is 1.6 μm, the leftmost side of a bond pad 284 can be spaced approximately 1.6 μm from the rightmost side of an immediately adjacent bond pad 284. Additionally, or alternatively, the leftmost side of a bond pad 284 positioned immediately adjacent an electrical contact 291 can be spaced approximately 1.6 μm from the rightmost side of the electrical contact 291.

Other pitches smaller or larger than 1.6 μm (e.g., 22.5 μm, 20 μm, 15 μm, 10 μm, 5 μm, 1 μm, 0.5 μm) are of course possible and within the scope of the present technology. Additionally, or alternatively, although the bond pads 284 and the electrical contacts 291 are illustrated as being uniformly spaced apart from one another, one or more of the bonds pads 284 and/or one or more of the electrical contacts 291 can be non-uniformly spaced apart from one another in other embodiments. In these and other embodiments, the widths of the bond pads 284 and/or the widths of the electrical contacts 291 can vary from one another, and/or can be larger than 0.8 μm or smaller than 0.5 μm in some embodiments. Additionally, or alternatively, the heights of the bond pads 284 and/or the heights of the electrical contacts 291 can vary from one another, and/or can be larger or smaller than 0.4 μm in various embodiments of the present technology.

The bond pads 284 and the electrical contacts 291 provide locations on the back side of the first and second semiconductor dies 290a and 290b at which electrical connections can be formed for passing supply voltages, signals, etc. between the first and second semiconductor dies 290a and 290b and the first and second semiconductor dies 210a and 210b, respectively. To facilitate passing supply voltages, signals, etc. through the bond pads 284, the TSVs 283 can be used to couple (a) corresponding bond pads 284 at the back side of the first and second semiconductor dies 290a and 290b to (b) corresponding ones of the landing pad structures 285, through the intermediate layers 292 of the first and second semiconductor dies 290a and 290b. In tun, the landing pad structures 285 can couple corresponding TSVs 283 to the metal layer 298 included in or coupled to BEOL layers 296 of the first and second semiconductor dies 290a and 290b.

Physical dimensions of the TSVs 283 can depend at least in part on the pitch and/or widths of the bond pads 284 and/or the electrical contacts 291. In the specific example above in which the bond pads 284 are arranged at a 1.6 μm pitch and are each approximately 0.5 μm to 0.8 μm in width, each of the corresponding TSVs 283 can be approximately 0.4 μm in width. Additionally, or alternatively, a distance between the bond pads 284 and the metal layer 298 can be approximately 2.2 μm such that the TSVs 283 are approximately 2.2 μm in height. Thus, continuing with this example, the TSVs 283 can have aspects ratios of height to widths of approximately 5.5:1. Thus, the TSVs 283 can also be referred to herein as nano-TSVs 283, or nTSVs 283. Furthermore, the bonds pads 284 of the semiconductor dies 290a and/or 290b can be considered part of the TSVs 283, especially in embodiments in which the bonds pads 284 and the TSVs 283 are formed with same material(s) and/or at the same time. Thus, a structure including a bond pad 284 and a corresponding TSV 283 can also be referred to herein as a dual damascene (DD) TSV and/or as a DD nano-TSV.

As discussed above, the first and second semiconductor dies 210a and 210b are stacked on the first and second semiconductor dies 290a and 290b, respectively, such that the bond pads 294 and the electrical contacts 272 of the semiconductor dies 210a and 210b are aligned with the bond pads 284 and the electrical contacts 291 of the semiconductor dies 290a and 290b, respectively. More specifically, dual damascene (DD) via structures (each including a bond pad 294 and a corresponding via) of the first and second semiconductor dies 210a and 210b are aligned with DD TSV or DD nano-TSV structures (each including a bond pad 284 and a corresponding TSV 283) of the first and second semiconductor dies 290a and 290b, respectively. The bonds pads 294 can be coupled to the bond pads 284. In this manner, supply voltages, signals, etc. can be passed (e.g., between the BEOL layers 296 of the first and second semiconductor dies 290a and 290b and the BEOL layers 216 of the first and second semiconductor dies 210a and 210b, respectively,) along or through the metal layer 298, one or more landing pad structures 285, one or more corresponding TSVs 283, one or more corresponding bond pads 284, one or more corresponding bond pads 294, one or more corresponding vias 293, and the interconnect structures 215. In these and other embodiments, electrical contacts 272 of the first and second semiconductor dies 210a and 210b can be aligned with and coupled to electrical contacts 291 of the first and second semiconductor dies 290a and 290b, respectively. As such, supply voltages, signals, etc. can be passed between the semiconductor dies 290a and 290b and the semiconductor dies 210a and 210b, respectively, via the electrical contacts 291 and the electrical contacts 272.

FIG. 3 is a flow diagram illustrating a method 330 of manufacturing a semiconductor device in accordance with various embodiments of the present technology. The semiconductor device can be the semiconductor device 100 of FIGS. 1A and 1B, the semiconductor device 200 of FIGS. 2A and 2B, the semiconductor device 250 of FIGS. 2A and 2B, and/or another semiconductor device of the present technology. The method 330 is illustrated as a series of steps or blocks 331-338. All or a subset of any one or more of the blocks 331-338 can be executed in accordance with the discussion above and/or the further discussion below. For the sake of clarity and explanation, the blocks 331-338 of the method 330 are discussed below with repeated reference to FIGS. 4A-4F that are partially schematic, cross-sectional side views of a semiconductor device 400 illustrating a series of steps for fabricating the semiconductor device 400 and/or a semiconductor device 450 (FIG. 4F), in accordance with various embodiments of the present technology.

The method 330 begins at block 331 by providing a first wafer having at least one semiconductor die. In some embodiments, providing the first wafer can include providing a first wafer bonded to a substrate (e.g., another wafer and/or a carrier substrate). For example, providing the first wafer can include bonding the first wafer to another wafer using a fusion bond. It is appreciated that providing the first wafer can include bonding the first wafer to another wafer using any other suitable type of bond. Additionally, or alternatively, providing the first wafer can include providing a first wafer having a front side bonded to a front side of the substrate.

In these and other embodiments, providing the first wafer can include providing a first wafer having at least one semiconductor die with one or more landing pad structures formed by and/or positioned within one or more intermediate layers (e.g., within one or more MOL layers and/or within one or more BEOL layers) of the at least one semiconductor die. Referring to FIG. 4A as an example, providing the first wafer can include providing a first wafer including at least one semiconductor die 410 having landing pad structures 405 formed at least in part by and/or positioned within intermediate layers 412 of the semiconductor die 410. In some embodiments, providing the first wafer can include leveraging, purposing, repurposing, and/or designing one or more metal layers in the intermediate layers 412 (e.g., in the MOL layers and/or in the BEOL layers of the semiconductor die 410) to provide at least part of the landing pad structure(s) 405. For example, providing the first wafer can include forming at least part of the landing pad structure(s) 405 in or using one or more metal layers in the intermediate layers 412. As a specific example, providing the first wafer can include forming at least part of the landing pad structure(s) 405 (e.g., landing pad components 405a and/or vertical components 405b) in, or using, a tungsten metal layer proximate a silicon layer within the intermediate layers 412 and/or a tungsten metal layer relatively further away from the silicon layer within the intermediate layers 412. In these and other embodiments, providing the first wafer can include forming the landing pad structure(s) 405 such that the landing pad structure(s) 405 (i) are coupled to a metal layer 414 (e.g., metal layer M1) of BEOL layers of the semiconductor die 410, and/or (ii) extend to one or more locations within the intermediate layers 412 at which one or more TSVs (discussed in greater detail below) can land or terminate.

In some embodiments, providing the first wafer can include providing a first wafer including at least one semiconductor die 410 having a stop layer 402 buried (e.g., implanted, embedded, submersed, formed) within a first layer 401 of the semiconductor die 410. The first layer 401 can be a silicon layer. Additionally, or alternatively, the stop layer 402 can be formed of SiO, SiGe, C, or another suitable material. In some embodiments, the stop layer 402 can be included to provide better TTV control or semiconductor wafer planarity/uniformity during a backside thinning process of the first layer 401 (discussed below).

At block 332, the method 330 continues by back grinding the at least one semiconductor die. In some embodiments, the back grinding can include removing material on a backside of the at least one semiconductor die, such as from the first layer of the at least one semiconductor die. Referring to FIG. 4A as an example, back grinding can include removing at least part of the portion of the first layer 401 that is positioned above the stop layer 402 in the illustrated embodiment.

At block 333, the method 330 continues by planarizing the at least one semiconductor die. Planarizing the semiconductor die(s) can include performing chemical-mechanical polishing (CMP) or another procedure to polish or planarize the semiconductor die(s). Referring to FIG. 4A as an example, planarizing the semiconductor die(s) can include performing CMP on a portion of the first layer 401 that remains positioned above the stop layer 402 after the back grinding performed at block 332.

At block 334, the method 330 continues by etching the at least one semiconductor die (e.g., to expose the stop layer). In some embodiments, etching the semiconductor die(s) can include dry etching the semiconductor die(s), such as with selective soft landing on the stop layer. In these and other embodiments, etching the semiconductor die(s) can include wet etching the semiconductor die(s). In some embodiments, the wet etching can include selectively wet etching the semiconductor die(s) with tetramethylammonium hydroxide (TMAH). Referring to FIGS. 4A and 4B as an example, etching the semiconductor die(s) can include wet or dry etching the semiconductor die 410 to remove remaining portions of the first layer 401 positioned above the stop layer 402 (as shown in FIG. 4A) such that the stop layer 402 is exposed at a backside of the semiconductor die 410 (as shown in FIG. 4B).

At block 335, the method 330 continues by forming a dielectric stack on the at least one semiconductor die, such as on the stop layer of the at least one semiconductor die. In some embodiments, forming the dielectric stack can include depositing one or more dielectric layers on the semiconductor die(s), such as on the exposed stop layer. Referring to FIG. 4C as an example, forming the dielectric stack can include forming a dielectric stack 406 that includes a plurality of layers. In the specific example illustrated in FIG. 4C, forming the dielectric stack 406 can include depositing a layer 407 on the stop layer 402 of the semiconductor die 410, depositing a layer 408 on the layer 407, and depositing a layer 409 on the layer 408. As discussed above, in some embodiments, the layer 407 can be formed of silicon carbon nitride, the layer 408 can be formed of silicon monoxide, and/or the layer 409 can be formed of silicon carbon nitride.

At block 336, the method 330 continues by forming TSVs, bond pads, and/or electrical contacts in the at least one semiconductor die. In some embodiments, forming the TSVs can include forming nano-TSVs. In these and other embodiments, forming the TSVs and the bond pads can include forming dual damascene TSVs. In these and still other embodiments, forming the TSVs and the bond pads can include forming dual damascene, nano-TSVs. Additionally, or alternatively, forming the TSVs, bond pads, and/or electrical contacts can include forming and/or arranging the TSVs, bond pads, and/or electrical contacts at a specified pitch (e.g., 1.6 μm).

In some embodiments, forming the TSVs, the bond pads, and/or the electrical contacts can include etching or otherwise forming voids or recesses in the semiconductor die(s). Referring to FIG. 4D as an example, forming the TSVs and/or the bond pads can include wet etching, drying etching, Bosch-type etching, or otherwise removing portions of the dielectric stack 406, the stop layer 402, the first layer 401 positioned beneath the stop layer 402, and/or one or more of the intermediate layers 412 to form recesses 441 that correspond to TSVs and/or bond pads. Etching the stop layer 402 can include dry etching, wet etching, or Bosch-type etching the stop layer 402 depending on the material composition of the stop layer 402. For example, in embodiments in which the stop layer 402 is formed of silicon germanium, the stop layer 402 can be wet etched with selective landing on the first layer 401 positioned beneath the stop layer 402. Forming the TSVs can include forming the recesses 441 such that the recesses 441 land or terminate on (e.g., landing pad components 405a of) the landing pad structures 405 and/or such that at least part of the landing pad structures 405 are exposed in the recesses 441. For example, forming the TSVs can include forming the recesses 441 such that the recesses 441 (or TSVs formed in the recesses 441) land on at least part of the landing pad structures 405 formed by a tungsten metal layer or another metal layer within the intermediate layers 412. In some embodiments, forming the TSVs includes forming recesses 441 that correspond to (a) dual damascene TSVs, (b) nano-TSVs, and/or (c) bond pads of the semiconductor die(s). Additionally, or alternatively, forming the electrical contacts can include etching or otherwise removing portions of the dielectric stack 406 to form recesses 440 that correspond to electrical contacts.

In these and other embodiments, forming the TSVs, the bond pads, and/or the electrical contacts can include depositing one or more materials (e.g., copper, tungsten, polysilicon, or another suitable material) within the voids or recesses formed in the semiconductor die(s) and/or planarizing the deposited materials. Referring to FIG. 4E as an example, forming the TSVs and the bond pads can include forming the TSVs and the bond pads together. For example, forming the TSVs and the bond pads can include depositing a material (e.g., copper, tungsten, polysilicon, or another suitable material) within the recesses 441 (FIG. 4D) to fill the portions of the recesses 441 that correspond to the TSVs 403 and to fill the portions of the recesses 441 that correspond to the bond pads 404. Depositing the material can include depositing the material such that the material contacts or is electrically coupled to portions (e.g., the landing pad components 405a) of the landing pad structures 105 exposed in the recesses 441. Forming the TSVs 403 and the bond pads 404 can further include planarizing the material, such as by performing CMP (e.g., such that a top surface of the material forming the bond pads 404 is flush with a top surface of the layer 409 of the dielectric stack 406). Because the TSVs 403 and the bond pads 404 can be formed together, a single etching step, a single material depositing step, and/or a single planarizing step may be used. In other words, the present technology can facilitate cost savings in comparison to methods of fabrication that form the TSVs 403 and the bond pads 404 separately and/or that use multiple etching steps, multiple material depositing steps, and/or multiple planarizing steps.

Alternatively, with continuing reference to FIG. 4E, the TSVs 403 can be formed (e.g., by (i) etching or otherwise removing portions of the stop layer 402, the first layer 401, and one or more of the intermediate layers 412 of the semiconductor die 410, (ii) filling the resulting recesses with a first material, and/or (iii) planarizing the first material) before forming the dielectric stack 406 and/or before forming the bond pads 404 and/or the electrical contacts 411. Continuing with this example, the dielectric stack 406 can thereafter be formed on top of the stop layer 402 and the TSVs 403. Then, the bond pads 404 and/or the electrical contacts 411 can be formed (e.g., by (i) etching or otherwise removing portions of the layers of the dielectric stack 406, such as portions of the layer 408 and/or the layer 409, (ii) filling the resulting recesses with a second material such that the second material is electrically coupled to the first material, and/or (iii) planarizing the second material).

In still other embodiments, forming the TSVs and the bond pads can include forming the TSVs and the bond pads separately. For example, forming the TSVs can include depositing a first material (e.g., copper, tungsten, polysilicon, etc.) in the recesses 441 to fill portions of the recesses 441 that correspond to TSVs 403. Depositing the first material can include depositing the first material such that the first material contacts or is electrically coupled to portions (e.g., the landing pad components 405a) of the landing pad structures 105 exposed in the recesses 441. In some embodiments, forming the TSVs 403 can further include planarizing the first material, such as by performing CMP (e.g., such that a top surface of the first material is flush with a top surface of the layer 407 of the dielectric stack 406). Forming the bond pads can additionally, or alternatively, include depositing a second material (e.g., copper, tungsten, polysilicon, etc.) in the recesses 441 to fill portions of the recesses 441 that correspond to bond pads 404. Depositing the second material can include depositing the second material on top of the first material within the recesses 441 and/or such that the second material contacts or is electrically coupled to the first material. The second material can be a same material as or a different material from the first material. Forming the bond pads 404 can further include planarizing the second material, such as by performing CMP (e.g., such that a top surface of the bond pads 404 is flush with a top surface of the layer 409 of the dielectric stack 406).

In these and other embodiments, forming the electrical contacts can include depositing one or more materials (e.g., copper, tungsten, polysilicon, or another suitable material) within the voids or recesses formed in the semiconductor die(s) and/or planarizing the deposited materials. Referring to FIG. 4E as an example, forming the electrical contacts 411 can include depositing a material (e.g., copper, tungsten, polysilicon, or another suitable material) within the recesses 440 (FIG. 4D) to fill the recesses 440. The material can be a same material as or a different material from the material(s) used to form the TSVs 403 and/or the bond pads 404. Forming the electrical contacts 411 can further include planarizing the material deposited in the recesses 440, such as by performing CMP (e.g., such that a top surface of the material forming the electrical contacts 411 is flush with a top surface of the layer 409 of the dielectric stack 406). The electrical contacts 411 can be formed at a same time as or at a different time from formation of the bond pads 404 and/or the TSVs 403.

At block 337, the method 330 continues by stacking a second wafer on the first wafer. Stacking the second wafer on the first wafer can include providing the second wafer. Providing the second wafer can include providing a second wafer having at least one semiconductor die with a dielectric stack, bond pads, electrical contacts, and/or TSVs. Referring to FIG. 4F as an example, providing the second wafer can include providing a second wafer having semiconductor die(s) 455 including a dielectric stack 456 at a front side of the semiconductor dies 455, bond pads 454 and/or electrical contacts 452 at the front side that are disposed in or on the dielectric stack 456, and vias 453 coupling the bond pads 454 to interconnect structures 451 through one or more layers 460. Providing the second wafer having semiconductor die(s) 455, can include forming the dielectric stack 456, the bond pads 454, the vias 453, and/or the electrical contacts 452 in a manner generally similar to forming the dielectric stack 406, the bond pads 404, the TSVs 403, and/or the electrical contacts 411, respectively, discussed above. For example, forming the bond pads 454 and the vias 453 can include forming (i) dual damascene TSVs, (ii) nano-TSVs, and/or (iii) dual damascene, nano-TSVs. Additionally, or alternatively, forming the bond pads 454, the vias 453, and/or the electrical contacts 452 can include forming and/or arranging the bond pads 454, the vias 453, and/or the electrical contacts 452 at a specified pitch (e.g., 1.6 μm), such as a pitch that matches or corresponds to the pitch of the bond pads 404, the TSVs 403, and/or the electrical contacts 411, respectively, of semiconductor die(s) 410 included in the first wafer.

Stacking the second wafer on the first wafer can include aligning electrical contacts with electrical contacts of the first wafer. Referring to FIG. 4F as an example, stacking the second wafer on the first wafer can include aligning the bond pads 454 of the semiconductor die(s) 455 with corresponding ones of the bond pads 404 of the semiconductor die(s) 410. In these and other embodiments, stacking the second wafer on the first wafer can include aligning dual damascene TSVs of the semiconductor die(s) 455 (each including a bond pad 454 and a corresponding via 453) with corresponding dual damascene TSVs, nano-TSVs, and/or dual damascene nano-TSVs of the semiconductor die(s) 410 (each including a bond pad 404 and a corresponding TSV 403). In these and other embodiments, stacking the second wafer on the first wafer can include aligning electrical contacts 452 of the semiconductor die(s) 455 with corresponding electrical contacts 411 of the semiconductor die(s) 410. Additionally, or alternatively, stacking the second wafer on the first wafer can include coupling bond pads 454 of the semiconductor die(s) 455 to corresponding bond pads 404 of the semiconductor die(s) 410 (e.g., to form electrical connections between the bonds pads 454 and the corresponding bond pads 404). Stacking the second wafer on the first wafer can include coupling the electrical contacts 452 of the semiconductor die(s) 455 to corresponding electrical contacts 411 of the semiconductor die(s) 410 (e.g., to form electrical connections between the electrical contacts 452 and the corresponding electrical contacts 411). In these and other embodiments, stacking the second wafer on the first wafer includes bonding the second wafer to the first wafer (e.g., using one or more hybrid bonds and/or one or more other suitable types of bonds). In these and still other embodiments, stacking the second wafer on the first wafer includes stacking the second wafer on the first wafer such that a front side of the semiconductor die(s) 455 interfaces with a backside of the semiconductor die(s) 410.

At block 338, the method 330 continues by dicing through the first and second wafers. Dicing through the first and second wafers can include singulating the wafers into one or more semiconductor devices 450 (FIG. 4F). One or more of the semiconductor devices 450 can include at least one semiconductor die 455 from the second wafer stacked on corresponding semiconductor die(s) 410 from the first wafer.

Although the steps 331-338 of the method 330 are discussed and illustrated in a particular order, the method 330 is not so limited. In other embodiments, the method 330 can be performed in a different order. In these and other embodiments, any of the steps 331-338 of the method 330 can be performed before, during, and/or after any of the other steps 331-338 of the method 330. Furthermore, the method 330 can be altered and still remain within these and other embodiments of the present technology. For example, one or more steps 331-338 (e.g., block 337 and/or block 338) of the method 330 can be omitted and/or repeated in some embodiments. As another example, the method 330 can include one or more additional steps than shown in FIG. 3. As a specific example, the method 330 can include one or more additional steps directed to (a) removing a substrate bonded to the front side of the first wafer; (b) forming a dielectric stack at the front side of the first wafer; (c) forming via structures, corresponding bond pads, and/or electrical contacts at the front side of semiconductor dies in the first wafer, such as in or on the dielectric stack and/or in one or more layers adjacent the dielectric stack; (d) providing a third wafer of semiconductor dies (e.g., similar to the semiconductor dies 290a and 290b of FIG. 2c); (e) stacking and/or bonding the first wafer on the third wafer (e.g., using a wafer-to-wafer fusion bond or other suitable bond); (f) dicing through the first, second, and/or third wafers; and/or (g) stacking and/or bonding the singulated/diced semiconductor devices 450 on semiconductor dies of the third wafer (e.g., using chip-to-wafer hybrid bonds, chip-to-chip bonds, or one or more other suitable types of bonds). Furthermore, although discussed above in the context of wafers including multiple semiconductor dies, all or a subset of one or more of the steps 331-338 of the method 330 can be employed to form a semiconductor device (e.g., the semiconductor device 450 of FIG. 4F) by forming and/or stacking singulated/diced semiconductor dies or sets of semiconductor dies constituting less than full wafers.

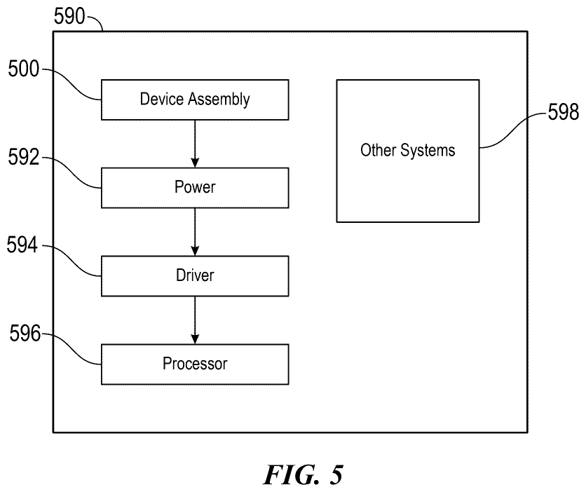

Any one of the semiconductor devices or semiconductor dies described above with reference to FIGS. 1A-4F can be incorporated into any of a myriad of larger and/or more complex systems, a representative example of which is system 590 shown schematically in FIG. 5. The system 590 can include a semiconductor device assembly 500, a power source 592, a driver 594, a processor 596, and/or other subsystems or components 598. The semiconductor device assembly 500 can include semiconductor devices and/or semiconductor dies with features generally similar to those of the semiconductor devices and/or semiconductor dies described above. The resulting system 590 can perform any of a wide variety of functions, such as memory storage, data processing, and/or other suitable functions. Accordingly, representative systems 590 can include, without limitation, hand-held devices (e.g., mobile phones, tablets, digital readers, and digital audio players), computers, and appliances. Components of the system 590 may be housed in a single unit or distributed over multiple, interconnected units (e.g., through a communications network). The components of the system 590 can also include remote devices and any of a wide variety of computer readable media.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings unless otherwise noted. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A semiconductor die, comprising:
a first side and a second side opposite the first side;
a bond pad at the first side,
a landing pad within an intermediate layer of the semiconductor die, the intermediate layer positioned between the first side and the second side, and
a via extending from the bond pad to the landing pad, the via having an aspect ratio of height to width that is 6:1 or less.

2. The semiconductor die of claim 1, wherein the intermediate layer is a middle-of-line (MOL) layer.

3. The semiconductor die of claim 1, wherein the intermediate layer is a back-end-of-line (BEOL) layer.

4. The semiconductor die of claim 1, wherein the via is a through-silicon via (TSV).

5. The semiconductor die of claim 1, wherein the via and the bond pad are formed of a same material.

6. The semiconductor die of claim 1, wherein the via is formed at least in part by copper.

7. The semiconductor die of claim 6, wherein the landing pad is formed at least in part by tungsten.

8. The semiconductor die of claim 1, further comprising:
a silicon layer positioned between the intermediate layer and the first side; and
a stop layer positioned between the silicon layer and the first side.

9. The semiconductor die of claim 8, wherein:
the semiconductor die further comprises a dielectric stack positioned between the stop layer and the first side; and
the bond pad is disposed in or on the dielectric stack.

10. The semiconductor die of claim 1, further comprising:
a metal layer positioned between the intermediate layer and the second side; and
a metal interconnect extending from the landing pad to the metal layer.

11. The semiconductor die of claim 10, wherein the metal interconnect is formed at least in part by tungsten.

12. The semiconductor die of claim 1, wherein the semiconductor die is a dynamic random-access memory (DRAM) die.

13. The semiconductor die of claim 1, wherein the semiconductor die is a logic die, a central processing unit (CPU) die, a graphics processing unit (GPU) die, or a tensor processing unit (TPU) die.

14. A semiconductor device, comprising:
a stack of semiconductor dies including a first semiconductor die and a second semiconductor die,
wherein the first semiconductor die has a first side and a second side opposite the first side, wherein the first semiconductor includes a first bond pad at the first side, a landing pad within an intermediate layer of the semiconductor die that is positioned between the first side and the second side, and a first via extending from the first bond pad to the landing pad, and further wherein the first via has an aspect ratio of height to width that is 6:1 or less, and
wherein the second semiconductor die has a third side and a fourth side opposite the third side, wherein the first and second semiconductor dies are arranged in the stack such that the third side of the second semiconductor die faces the first side of the first semiconductor die, wherein the second semiconductor die includes a second bond pad at the third side that is aligned with and coupled to the first bond pad of the first semiconductor die, wherein the second semiconductor die includes a second via coupled to the second bond pad and extending from the second bond pad toward the fourth side, and further wherein the second via has an aspect ratio of height to width that is 6:1 or less.

15. The semiconductor device of claim 14, wherein the intermediate layer is a middle-of-line (MOL) layer of the first semiconductor die.

16. The semiconductor device of claim 14, wherein the intermediate layer is a back-end-of-line (BEOL) layer of the first semiconductor die.

17. The semiconductor device of claim 14, wherein:
the first semiconductor die includes (i) a first plurality of bond pads arranged at a first pitch at the first side of the first semiconductor die, (ii) a plurality of landing pads within the intermediate layer, and (iii) a first plurality of vias, each via of the first plurality of vias extending from a respective bond pad of the first plurality of bond pads to a respective landing pad of the plurality of landing pads and having an aspect ratio of height to width of 6:1 or less;
the second semiconductor die includes (i) a second plurality of bond pads arranged at a second pitch at the third side and (ii) a second plurality of vias, each via of the second plurality of vias extending from a respective bond pad of the second plurality of bond pads toward the fourth side; and
the second pitch corresponds to the first pitch such that each bond pad of the first plurality of bond pads is aligned with and coupled to a respective bond pad of the second plurality of bond pads.

18. The semiconductor device of claim 14, wherein:
the stack of semiconductor dies further includes a third semiconductor die having a fifth side and a sixth side opposite the fifth side;
the first semiconductor die, the second semiconductor die, and the third semiconductor die are arranged in the stack such that (a) the fifth side of the third semiconductor die faces the second side of the first semiconductor die (b) the first semiconductor die and the second semiconductor die are stacked on the third semiconductor die, and (c) the second semiconductor die is stacked on the first semiconductor die;
the first semiconductor die includes (i) a first plurality of bond pads arranged at a first pitch at the second side and (ii) a first plurality of vias, each via of the first plurality of vias extending from a respective bond pad of the first plurality of bond pads toward the first side;
the third semiconductor die includes (i) a second plurality of bond pads arranged at a second pitch at the fifth side and (ii) a second plurality of vias, each via of the second plurality of vias extending from a respective bond pad of the second plurality of bond pads toward the sixth side and having an aspect ratio of height to width that is 6:1 or less; and
the second pitch corresponds to the first pitch such that each bond pad of the first plurality of bond pads is aligned with and coupled to a respective bond pad of the second plurality of bond pads.

19. The semiconductor device of claim 18, wherein:
the first semiconductor die, the second semiconductor die, or both the first semiconductor die and the second semiconductor die is/are memory die; and
the third semiconductor die is a logic die, a central processing unit (CPU) die, a graphics processing unit (GPU) die, or a tensor processing unit (TPU) die.
